(19) United States
(12) Patent Application Publication
(10) Pub. No.: US 2010/0209628 A1
(43) Pub. Date: Aug. 19, 2010

(54) GROWTH OF COATINGS OF NANOPARTICLES BY PHOTOINDUCED CHEMICAL VAPOR DEPOSITION

(75) Inventors: Steven L. Girshick, Minneapolis, MN (US); Bin Zhang, Vista, CA (US); Toshitaka Nakamura, Oceanside, CA (US); Amane Mochizuki, San Diego, CA (US); Jeffrey Roberts, Falcon Heights, MN (US); Ying-Chin Liao, Corvallis, OR (US); Yuanqing He, Evansville, IN (US); Adam Boies, Minneapolis, MN (US)

Correspondence Address: SCHWEGMAN, LUNDBERG & WOESSNER, P.A., P.O. BOX 2938, MINNEAPOLIS, MN, 55402, US

(73) Assignee: Regents of the University of Minnesota, St. Paul, MN (US)

(21) Appl. No.: 12/596,683

(22) PCT Filed: Apr. 17, 2008
(86) PCT No.: PCT/US08/05112

§ 371 Date: Apr. 16, 2010

Related U.S. Application Data
(60) Provisional application No. 60/925,473, filed on Apr. 20, 2007.

(51) Int. Cl. C23C 16/48; C23C 16/00

(52) U.S. Cl. 427/595; 118/724; 977/773; 977/891

(57) ABSTRACT

Photoinduced chemical vapor deposition was used to grow coatings on nanoparticles. Aerosolized nanoparticles were mixed with a vapor-phase coating reactant and introduced into a coating reactor, where the mixture was exposed to ultraviolet radiation. Tandem differential mobility analysis was used to determine coating thicknesses as a function of initial particle size.

### RELATED APPLICATIONS

This application claims priority under 35 U.S.C. §119(e) to U.S. Provisional Patent Application No. 60/925,473, filed Apr. 20, 2007, which is incorporated herein by reference.

### BACKGROUND OF THE INVENTION

Nanoparticles are very small particles typically ranging in size from one nanometer to several hundred nanometers in diameter. Their small size allows nanoparticles to be exploited to produce a variety of products such as dyes and pigments; aesthetic or functional coatings; tools for biological discovery, medical imaging, and therapeutics; magnetic-recording media; quantum dots; and uniform and nanosize semiconductors.

For nanoparticles to be useful in a wide variety of applications, methods should be developed to control their surface properties. In some cases the goal is to stabilize or passivate the nanoparticle surfaces, in other cases to impart some desired functionality. The former can be accomplished by coating the nanoparticle with a thin film, producing a “core-shell” structure, and the latter can be achieved by attaching chemical functional groups to the nanoparticle surface.

A variety of methods have been developed for coating or modifying nanoparticle surfaces. While most work has involved liquid-based chemistry, gas-phase (i.e., aerosol) methods are also being explored. Gas-phase methods allow greater purity, as solution-based methods usually involve a pre-activation step, typically with a solvent or catalyst, leaving unwanted trace compounds or elements on the nanoparticle surfaces. Aerosol-based approaches for nanoparticle surface modification include heated flow tubes, flames, spray pyrolysis, microwave plasma, and RF plasma.

Furthermore, gas-phase methods can be run as continuous rather than batch processes, do not involve management and disposal of environmentally hazardous solvents, and are obviously more compatible with systems in which the core nanoparticles are themselves synthesized in gas phase.

### SUMMARY OF INVENTION

The present invention provides a method of coating nanoparticles with various materials by photo-assisted chemical vapor deposition (photo-CVD), driven by vacuum ultraviolet (VUV) radiation. Photo-assisted chemical vapor deposition has potential advantages over solution-based methods that include, for example, greater purity, a continuous process, no solvent requirements, room-temperature operation, atmospheric-pressure operation, and/or the ability to use excimer lamps, which are economical, easy to use, and/or readily incorporated into any type of gas-phase nanoparticle synthesis system.

The present invention also provides a method of coating nanoparticles. The method includes exposing aerosolized nanoparticles to a gas-phase reactant and ultraviolet radiation simultaneously; and depositing a coating on one or more surfaces of the aerosolized nanoparticles.

In one embodiment, the method further includes controlling the thickness of the deposition of the coating on the one or more surfaces of the aerosolized nanoparticles including varying a flow rate of the aerosolized nanoparticles, varying a flow rate of the gas-phase reactant, varying an optional flow rate of an optional purge gas, or a combination thereof. In one embodiment, the ultraviolet radiation is transmitted through an ultraviolet interference filter before the exposing aerosolized nanoparticles to a gas-phase reactant and ultraviolet radiation simultaneously. In one embodiment, the method further includes generating the ultraviolet radiation employing an excimer lamp.

In one embodiment, the exposing aerosolized nanoparticles to a gas-phase reactant and ultraviolet radiation simultaneously is carried out at a temperature from about −100° C. to about 600° C. In one embodiment, the exposing aerosolized nanoparticles to a gas-phase reactant and ultraviolet radiation simultaneously is carried out at a pressure from about 0.5 kPa to about 500 kPa. In one embodiment, the ultraviolet radiation has a wavelength from about 80 nm to about 400 nm.

In one embodiment, the flow rate of aerosolized nanoparticles is from about 0.1 standard cubic centimeters per minute (sccm) to about 500 sccm. In one embodiment, the flow rate of the gas-phase reactant is from about 0.1 sccm to about 100 sccm. In one embodiment, the optional flow rate of an optional purge gas is from about 0.1 sccm to about 50,000 sccm.

In one embodiment, the aerosolized nanoparticles comprise nonpolymeric inorganic materials, polymeric inorganic materials, nonpolymeric organic materials, polymeric organic materials, or combinations thereof. In one embodiment, the nonpolymeric inorganic materials comprise an inorganic salt, a transition metal, a non-metal, an inorganic oxide, or a combination thereof. In one embodiment, the inorganic salt includes sodium chloride. In one embodiment, the transition metal includes Pd, Pt, Ni, Co, Rh, Ir, Fe, Ru, Au, Ag, Cu, or a combination thereof. In one embodiment, the inorganic oxide includes silicon dioxide, iron oxide, or a combination thereof.

In one embodiment, the gas-phase reactant includes a gas-phase organic reactant, a gas-phase inorganic reactant, or a combination thereof. In one embodiment, the gas-phase organic reactant includes (C₁-C₂₄)alkanes, (C₂-C₂₄)alkenes, (C₂-C₂₄)alkynes, (C₃-C₂₄)cycloalkanes, (C₆-C₁₈)aromatics, or combinations thereof. In one embodiment, the gas-phase organic reactant includes CH₄, C₂H₄, C₂H₆, styrene, methyl methacrylate (MMA), or combinations thereof.

In one embodiment, the gas-phase inorganic reactant includes silane, N₂O, tetramethoxysilane, tetraethoxyorthosilicate, ammonia, Si₂H₆, trimethylaluminum, tantalum ethoxide, Mo(CO)₆, Fe(CO)₅, or combinations thereof.

In one embodiment, the coating includes an organic coating, an inorganic coating, or a hybrid organic-inorganic coating. In one embodiment, the organic coating includes amorphous carbon, hydrogenated carbon (a-C:H), or combinations thereof. In one embodiment, the inorganic coating includes aluminum, amorphous silicon, amorphous hydrogenated silicon (a-Si:H), hafnia, iron oxide, molybendenum, silicon oxide, silicon carbide, silicon dioxide, silicon nitride, tantalum pentoxide, titanium oxide, zirconia, or combinations thereof.

In one embodiment, the coating is substantially continuous. In one embodiment, the coating is not substantially continuous.

The present invention further provides a method of coating nanoparticles. The method includes introducing a flow of aerosolized nanoparticles into a coating reactor; introducing a flow of a gas-phase reactant into the coating reactor; introducing an optional flow of an optional purge gas into the coating reactor; exposing the coating reactor to ultraviolet radiation, wherein the ultraviolet radiation is generated using an excimer lamp; depositing a coating on one or more surfaces of the aerosolized nanoparticles; and controlling the thickness of the deposition of the coating on the one or more surfaces of the aerosolized nanoparticles.

In one embodiment, the controlling the thickness of the deposition of the coating on the one or more surfaces of the aerosolized nanoparticles includes varying a flow rate of the aerosolized nanoparticles, varying a flow rate of the gas-phase reactant, varying a flow rate of an optional purge gas, or a combination thereof.

The present invention also provides a nanoparticle coating system. The nanoparticle coating system includes a coating reactor; a flow of a gas-phase reactant coupled to the coating reactor; a flow of aerosolized nanoparticles coupled to the coating reactor; an optional flow of an optional purge gas coupled to the coating reactor; and

a source of ultraviolet radiation configured to expose the coating reactor to ultraviolet radiation.

In one embodiment, the nanoparticle coating system further includes an ultraviolet interference filter through which the ultraviolet radiation is transmitted before exposing the coating reactor. In one embodiment, the source of ultraviolet radiation includes an excimer lamp.

### DEFINITIONS

Unless otherwise indicated, the words and phrases presented in this document have their ordinary meanings to one of skill in the art. Such ordinary meanings can be obtained by reference to their use in the art and by reference to general and scientific dictionaries, for example, Webster's New World Dictionary, Simon & Schuster, New York, N.Y., 1995, The American Heritage Dictionary of the English Language, Houghton Mifflin, Boston Mass., 1981, and Hawley's Condensed Chemical Dictionary, 14^{th} edition, Wiley Europe, 2002.

The following explanations of certain terms are meant to be illustrative rather than exhaustive. These terms have their ordinary meanings given by usage in the art and in addition include the following explanations.

As used herein, the term “about” refers to a variation of 10 percent of the value specified; for example about 50 percent carries a variation from 45 to 55 percent.

As used herein, the term “and/or” refers to any one of the items, any combination of the items, or all of the items with which this term is associated.

As used herein, the singular forms “a,” “an,” and “the” include plural reference unless the context clearly dictates otherwise.

As used herein, the term “amorphous carbon” refers to a material composed of a mixture of “sp²” and “sp^{a}” bonded carbon. “Sp²” bonded carbon refers to double bonded carbon. “Sp³” bonded carbon refers to single bonded carbon. Amorphous carbon does not possess a highly ordered crystalline structure.

As used herein, the term “amorphous, hydrogenated carbon” or “a-C:H” refers to a carbon material, in which an amorphous carbon network-type structure that contains bonded hydrogen atoms exists.

As used herein, the term “bioactive agent” refers to any drug, organic compound, substance, nutrient or biologically beneficial agent including proteins, peptides (including polypeptides and oligopeptides), hormones, vaccines, oligonucleotides, genes, nucleic acids, steroids, antibiotics, antibodies, viruses, live cells, and other chemotherapeutic or non-therapeutic agents without limitation.

As used herein, the term “coating reactor” refers to the chamber in which the gas-phase reactant interacts the ultraviolet light.

As used herein, the term “composite material” refers to combination of two or more differing materials.

As used herein, the term “drug” refers to a chemical capable of administration to an organism which modifies or alters the organism's physiology. More preferably, as used herein, the term “drug” refers to any substance intended for use in the treatment or prevention of disease, particularly for humans. Drug includes synthetic and naturally occurring toxins and bioaffecting substances as well as recognized pharmaceuticals, such as those listed in The Merck Index, 14^{th} Ed., Merck Research Laboratories, Whitehouse Station, N.J., 2006, The Physicians Desk Reference, 62^{nd} edition, 2008, pages 101-201, Thomson Healthcare Inc., Montvale, N.J.; Goodman and Gilman's The Pharmacological Basis of Therapeutics, 8^{th} Edition (1990), pages 84-1614 and 1655-1715; and The United States Pharmacopeia, The National Formulary, USP XXII NF XVII (1990), the compounds of these references being herein incorporated by reference.

As used herein, the term “effective coating thickness” refers to a one-half the peak shift, where each of the central modes of the size distributions (ignoring the satellite peaks) is fit with a Gaussian.

As used herein, the term “excimer lamp” refers to a discharge lamp that emits high-intensity excimer light. There are many other names to refer to this excimer lamp, such as “high power radiator,” which focuses on the feature of emitting high-power excimer light; “dielectric barrier discharge lamp,” which focuses on the dielectric barrier discharge feature; “electrodeless field discharge excimer lamp,” which focuses on the fact that there are no electrodes in the discharge container, as indicated by the term “electrodeless,” and that a high-frequency voltage is applied to the electrodes placed on each outside lateral surface of the discharge container, as indicated by the term “field discharge.” These lamps are referred herein as “excimer lamps.”

As used herein, the phrase “in one embodiment” refers a particular feature, structure, or characteristic. However, every embodiment may not necessarily include the particular feature, structure, or characteristic. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein, the term “inorganic material” refers to any material that is not organic.

As used herein, the term “liquid” refers to a substance that undergoes continuous deformation under a shearing stress. See, e.g., Concise Chemical and Technical Dictionary, 4^{th} Edition, Chemical Publishing Co., Inc., p. 707, New York, N.Y. (1986).

As used herein, the term “nanoparticles” refers to a particle having at least one dimension equal to or smaller than about 500 nm, preferably equal to or smaller than about 100 nm, more preferably equal to or smaller than about 50 or about 20 nm, or having a crystallite size of about 10 nm or less, as measured from electron microscope images and/or diffraction peak half widths of standard 2-theta x-ray diffraction scans.

As used herein, the term “organic material” refers to a carbon and hydrogen containing compound.

As used herein, the term “polymeric inorganic material” refers to a polymeric material having a backbone repeat unit based on an element or elements other than carbon, while the term “polymeric organic material” means synthetic polymeric materials, semi-synthetic polymeric materials and/or natural polymeric materials having a backbone repeat unit based on carbon.

As used herein, the recitations of numerical ranges by endpoints include all numbers subsumed within that range (e.g., 1 to 5 includes 1, 1.5, 2, 2.75, 3, 3.80, 4, 5, etc.).

As used herein, the term “substantially continuous,” when used with respect to “the coating is substantially continuous” refers to a film that forms a substantially contiguous coating where formed on the nanoparticles.

As used herein, the term “transition metal” refers to all metal atoms in the Periodic Table of Elements from Sc to Zn, Y to Cd and La to Hg including rare earths and actinides metals.

As used herein, the term “ultraviolet radiation” refers to radiation whose wavelength is in the range from about 80 nm to about 400 nm.

### BRIEF DESCRIPTION OF THE FIGURES

FIG. 1 is a representation of measured size distributions for particles produced by photoinduced nucleation from either C₂H₂ or CH₄.

FIG. 2 is a representation of measured size distributions of particles produced by photoinduced nucleation for 1.5 sccm of C₂H₂ with various flow rates of hydrogen.

FIG. 3 is a representation of tandem differential mobility analysis measurements of bare and coated 40 nm sodium chloride particles using 0.5 sccm of C₂H₂ as the coating reactant (including satellite peaks, left).

FIG. 4 is a representation of measurements of tandem differential mobility analysis for 1 sccm of C₂H₂ mixed with 41 nm sodium chloride particles when ultraviolet was on and off, with measurements of the coated particles taken at four different times.

FIG. 5 is a representation of variation of coating thickness with C₂H₂ flow rate for 40 nm sodium chloride particles.

FIG. 6 is a representation of variation of coating thickness with methyl methacrylate flow rate for 40 nm sodium chloride particles.

FIG. 7 is a representation of variation of coating thickness with methyl methacrylate flow rate for sodium chloride particles of various initial diameters.

FIG. 8 is a representation of effect of ultraviolet radiation on measured size distributions of sodium chloride particles using interference filters with different transmittances. (Negatively-charged particles introduced from DMA1).

FIG. 9 is a representation of variation of coating thickness with methyl methacrylate flow rate for sodium chloride particles for various ultraviolet intensities.

FIG. 10 is a representation of measured size distributions of background and the particles produced by photoinduced nucleation with 22.9 sccm of methyl methacrylate and the filter of 50% transmittance used.

FIG. 11 is a representation of variation of coating thickness with relative total particle concentration after dilution.

FIG. 12 is a representation of transmission electron microscopy images of particles collected after mobility classification by DMA1 at 41 nm. (a) A bare sodium chloride particle. (b) The core sodium chloride particle surrounded by an amorphous shell.

FIG. 13 is a representation of infrared spectra of sodium chloride nanoparticles with and without methyl methacrylate coating. Spectra of methyl methacrylate and poly methylmethacrylate are also shown for reference.

FIG. 14 is a representation of size distribution of aluminum particles synthesized by thermal plasma when the chamber pressure was 100 kPa and the flow rate of H₂ was 0.2 standard liter per minute (slm, wherein 1 slm=1000 standard cubic centimeter per minute (sccm)).

FIG. 15 is a representation of measured size distributions of coated 30 nm and 40 nm aluminum particles (left). Normalized size distributions of bare and coated 40 nm particles and ultraviolet radiation and 0.1 sccm CH₄ were introduced.

FIG. 16 is a representation of variation of coating thickness with methyl methacrylate flow rate for 40 nm sodium chloride and aluminum particles.

FIG. 17 is a representation of transmission electron microscopy images of particles collected after mobility classification by DMA1 at 41 nm. The bare aluminum particle (left). The core aluminum particle surrounded by a coating shell (right).

FIG. 18 is a representation of SMPS measurements of particle concentration with various charging effects.

FIG. 19 is a representation of (A) Agglomerated silver particles produced without sintering (B) Coalesced particles produced with second tube furnace at 600° C.

FIG. 20 is a representation of Coating thickness of silver particles for varying TEOS precursor flowrate and initial particle size.

FIG. 21 is a representation of Coating thickness of silver particles for varying TEOS precursor flowrate with different purge nitrogen flowrates.

FIG. 22 is a representation of (A) Schematic of particle/TEOS inlet positions into coating chamber (B) Coating thickness of silver particles for varying TEOS precursor flowrate and different particle/precursor inlet positions.

FIG. 23 is a representation of (A) Schematic of particle system configuration (B) Coating thickness of silver particles for varying TEOS precursor flowrate and different system configurations

FIG. 24 is a representation of TEM images of silica coated size selected silver particle.

FIG. 25 is a representation of TDMA analysis of YAP particle diameter with varying TEOS flowrate.

FIG. 26 is a representation of Coating thickness for on YAP particles for varying TEOS flowrates and transmitted UV power.

FIG. 27 is a representation of TEM analysis of (A) bare and (B) coated YAP particles.

### DETAILED DESCRIPTION OF INVENTION

The present invention provides a method of coating nanoparticles with various materials by photo-assisted chemical vapor deposition (photo-CVD), driven by vacuum ultraviolet (VUV) radiation. Photo-assisted chemical vapor deposition has potential advantages over solution-based methods that include, for example, greater purity, a continuous process, no solvent requirements, room-temperature operation, atmospheric-pressure operation, and/or the ability to use excimer lamps, which are economical, easy to use, and/or readily incorporated into any type of gas-phase nanoparticle synthesis system.

The present invention also provides a method of coating nanoparticles. The method includes exposing aerosolized nanoparticles to a gas-phase reactant and ultraviolet radiation simultaneously; and depositing a coating on one or more surfaces of the aerosolized nanoparticles.

Several distinct phenomena may occur during photo-assisted chemical vapor deposition. Ultraviolet photons can dissociate reactant molecules, generating radical species that can then react on nanoparticle surfaces to grow films. Alternatively, UV-generated radicals can initiate homogeneous nucleation of particles from the reactant gas. Chemical species arriving at nanoparticle surfaces can interact synergistically with ultraviolet photons to grow a film. Ultraviolet radiation arriving at a surface can modify its chemical structure, or can change the particle charge state by photoemission. Many of these processes are likely to be different for nanoparticles, which in many cases are much smaller than the mean free path in the gas (free molecule regime), than for larger particles or macroscopic substrates, where a diffusive boundary layer forms.

Applications of these core-shell nanoparticles include, for example, solid fuel propulsion, photovoltaics, photonics, biological imaging, and tumor destruction. Aluminum nanoparticles are of interest as solid fuel propulsion, however their surfaces should be passivated to avoid premature oxidation. Under ambient conditions, passivation occurs naturally, via the formation of a thin native oxide layer on the nanoparticles. While the oxide layer can inhibit further diffusion of oxygen into the aluminum core, it should be cracked open before the nanoparticle can burn, which is difficult and highly endothermic, as the oxide melting temperature is quite high. Alternatively, coating each nanoparticle may be coated with, for example, a hydrogenated amorphous organic film as an oxygen diffusion barrier, as is done for plastic beverage bottles. In this case, the nanoparticle coating can prevent undesired pre-combustion, and may be used as a fuel that can burn off quickly when ignited.

Silicon nanoparticles have potential applications as biosensors, in optical devices, and as building blocks of nanoscale electronic devices. Among the most intensely studied applications of Si nanoparticles are the optical ones. In nanocrystalline form, Si effectively becomes a direct bandgap material. This, along with other effects related to quantum confinement, means that Si nanoparticles exhibit intense photoluminescence in the visible spectrum. Other advantages of Si include low toxicity, low cost, and generally high compatibility with other materials.

For Si nanoparticles to be useful in the applications noted above, the silicon nanoparticle surface should be passivated or chemically functionalized. For example, surface oxidation by air can change and degrade the photoluminescent properties of nanoparticle Si. Another issue for some applications, especially sensors and biological labels, is how to direct the nanoparticle attachment to specific sites on a substrate. One strategy for doing this is to modify the nanoparticle so that the particle surface terminates in a chemical functional group (e.g., —OH, —CO₂H, —CO₂CH₃) that preferentially adsorbs to specific sites of interest.

Such layers can protect Si from reaction with ambient gases, and, in the case of nanoparticle Si, they can preserve photoluminescence. There is a rich literature on the functionalization and derivatization of planar Si surfaces with organic monolayers via hydrosilation chemistry via reactions of the general form

Si—H+R—H→Si—R+H₂,

wherein Si—H is a silicon-hydrogen bond at the Si surface and R is some organic functional group. This type of chemistry is an efficient means of grafting a diverse range of organic groups to the Si surface, including alkenes and alkynes, aldehydes and alcohols, and amines.

Magnetic iron oxide nanoparticles (both γ-Fe₂O₃ and Fe₃O₄) are currently the subject of intense study because of their importance in high-density data storage, catalysis and medical applications. The latter include the use of magnetic nanoparticles as contrast-enhancing agents for cancer detection using magnetic resonance imaging, as miniaturized heaters capable of killing malignant cells and as targeted drug delivery vehicles. For iron oxide nanoparticles to be useful in such applications, they should be coated improve chemical stability, to prevent aggregation, and, in many cases, to serve as a substrate for biofunctionalization. For biological applications, considerations may include, for example, dispersibility in biological tissue, biocompatibility, and the ability of the particle surface to be biofunctionalized.

There are several configurations for the photoinduced chemical vapor deposition coating reactor. In one embodiment, both the nanoparticles and coating reagent are exposed to ultraviolet radiation. In one embodiment, the coating reagent is exposed to ultraviolet radiation, after which nanoparticles are introduced out of the radiation line of sight. The relative importance of gas-phase versus surface processes may of course depend on the choice of coating reactant, and, for a given coating reactant, on the ultraviolet wavelength.

In one embodiment, there are two gases in the coating reactor including one gas that includes the aerosolized nanoparticles and another gas that includes a reactant. If the flow rate of the aerosolized nanoparticles is much larger than the flow rate of the reactant, then the flow rate of the aerosolized nanoparticles controls the residence time inside the coating reactor. If the flow rate of the reactant is much larger than the flow rate of the aerosolized nanoparticles, then the flow rate of the reactant controls the residence time inside the coating reactor.

In another embodiment, there are three gases in the coating reactor including one gas that includes the aerosolized nanoparticles, another gas that includes a reactant, and a purge gas. If the flow rate of the aerosolized nanoparticles is much larger than the flow rate of the reactant and the flow rate of the purge gas, then the flow rate of the aerosolized nanoparticles controls the residence time inside the coating reactor. If the flow rate of the reactant is much larger than the flow rate of the aerosolized nanoparticles and the flow rate of the purge gas, then the flow rate of the reactant controls the residence time inside the coating reactor. If the flow rate of the purge gas is much larger than the flow rate of the aerosolized nanoparticles and the flow rate of the reactant, then the flow rate of the purge gas controls the residence time inside the coating reactor.

### Nanoparticles

Depending on the desired properties and characteristics of the coated nanoparticles, it will be recognized by one skilled in the art that different particles and/or different average particle sizes can be used.

Suitable nanoparticles may include, for example, any of the nanosized inorganic, organic, or inorganic/organic hybrid materials known in the art. For example, the nanoparticles may include polymeric inorganic materials, nonpolymeric inorganic materials, polymeric organic materials, nonpolymeric organic materials, or combinations thereof.

Suitable nonpolymeric inorganic materials may include, for example, an inorganic salt, a transition metal, a metal alloy, a non-metal, an inorganic oxide, or a combination thereof.

Suitable inorganic salts may include, for example, borides, carbides, halides hydroxides, nitrides, oxides, sulfates, sulfide, silicates, or combinations thereof. Suitable nanoparticles may include, for example, inorganic salts such as metal halides. Suitable metal halides may include, for example, LiF, LiCl, LiBr, LiI, NaF, NaCl, NaBr, NaI, KF, KCl, KBr, KI, and the like, or combinations thereof.

Suitable transition metals may include, for example, Pd, Pt, Ni, Co, Rh, Ir, Fe, Ru, Au, Ag, Cu, or a combination thereof. Suitable nonpolymeric inorganic materials may also include, for example, silicon.

Suitable metal alloys may include, for example, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, and HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GalnPAs, GalnPSb, InAlNP, InAlNAs, InAlNSb, InAIPAs, InAIPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe SnPbSTe, and the like, or combinations thereof.

Suitable nanoparticles may include, for example, inorganic oxides such as titanium dioxide, titanium oxide, tin oxide, silicon dioxide, iron oxide, zirconium oxide, zinc oxide, aluminum oxide, cerium oxide, tin oxide, yttrium oxide, antimony pentoxide, silica-titania, indium tin oxide, antimony tin oxide, and the like, or combinations thereof.

Suitable nanoparticles may include, for example, ceramic materials such as brushite, tricalcium phosphate, silicon carbide, boron carbide, tungsten carbide, silicon nitride, boron nitride, tungsten nitride, zirconia, magnesium stabilized zirconia, zirconia stabilized alumina, yttrium stabilized zirconia, calcium stabilized zirconia, titania, magnesia, niobia, vanadia, cordierite, cordierite-alpha alumina, zircon mullite, spodumene, alumina-silica magnesia, zircon silicate, sillimanite, magnesium silicates, zircin, petalite, carbon black, calcium oxide, barium sulfate, silica, silica-alumina, alumina, alumina-zirconia, alumina-chromia, alumina-ceria, mica, talc, gypsum, kaolinite, calcite, cadmium iodide, silver sulfide, molybdenum diselenide, tantalum diselenide, tungsten diselenide and mixtures thereof, as well as stearates (such as zinc stearate and aluminum stearate), and stearamide, or combinations thereof.

Suitable polymeric inorganic materials may include, for example, graphite, diamond, polyphosphazenes, polysilanes, polysiloxanes, polygermanes, polymeric sulfur, polymeric selenium, silicones, or combinations thereof.

Suitable nonpolymeric organic materials may include, for example, organic compounds such as non-polymeric bioactive agents, drugs, prodrugs, or metabolites thereof; dyes, pigments, and the like, or combinations thereof.

Suitable polymeric organic materials may include, for example, thermoplastic polyesters such as polyethylene terephthalate, polybutylene terephthalate and polyethylene naphthalate, polycarbonates, polyolefins such as polyethylene, polypropylene and polyisobutene, acrylic polymers such as copolymers of styrene and an acrylic acid monomer and polymers containing methacrylate, polyamides, thermoplastic polyurethanes, vinyl polymers, and mixtures thereof; and thermoset materials such as thermoset polyesters, vinyl esters, epoxy materials, phenolics, aminoplasts, thermoset polyurethanes and mixtures thereof.

Suitable polymeric organic materials may include, for example, bioactive agents such as biopolymers including polypeptides, carbohydrates, nucleic acids, and the like, or combinations thereof.

In an exemplary embodiment, the size of the nanoparticles is preferably from about 5 nm to about 150 nm (mean diameter), more preferably from about 5 to about 50 nm, most preferably from about 10 to about 30 nm. The nanoparticles may also be rods.

The flow rate of the aerosolized nanoparticles may be at any desired rate. In an exemplary embodiment, the flow rate of the aerosolized nanoparticles may be from about 0.1 standard cubic centimeters per minute (sccm) to about 5000 sccm, preferably from about 250 sccm to about 3000 sccm, more preferably from about 500 sccm to about 1500 sccm.

### Nanoparticle Coating

Depending on the desired properties and characteristics of the coated nanoparticles, it will be recognized by one skilled in the art that different coatings on the surface of the nanoparticles may be used. The coatings on the surface of the nanoparticles may include, for example, any inorganic, organic, or inorganic/organic hybrid material known in the art.

The methods, as disclosed herein, may be used to prepare organic coatings on organic nanoparticles, organic coatings on inorganic nanoparticles, inorganic coatings on organic nanoparticles, inorganic coatings on inorganic nanoparticles, hybrid organic-inorganic coatings on organic nanoparticles, hybrid organic-inorganic coatings on inorganic nanoparticles.

Suitable organic materials to be coated on the surface of the nanoparticles may include, for example, amorphous carbon, hydrogenated carbon (a-C:H), and the like, or combinations thereof.

Suitable inorganic materials to be coated on the surface of the nanoparticles may include, for example, aluminum, amorphous silicon, amorphous hydrogenated silicon (a-Si:H), hafnia, iron oxide, molybendenum, silicon oxide, silicon dioxide, silicon carbide, silicon nitride, tantalum pentoxide, zirconia, titanium oxide, and the like, or combinations thereof.

Suitable gas-phase organic reactants may include, for example, (C₁-C₂₄)alkanes, (C₂-C₂₄)alkenes, (C₂-C₂₄)alkynes, (C₃-C₂₄)cycloalkanes, (C₆-C₁₈)aromatics, and the like, or combinations thereof. Suitable gas-phase organic reactants may include, for example, CH₄, C₂H₄, C₂H₆, styrene, methyl methacrylate (MMA), and the like, or combinations thereof.

Suitable gas-phase inorganic reactants may include, for example, silane (SiH₄), N₂O, tetramethoxysilane (TMOS), tetraethoxyorthosilicate (TEOS, Si(OC₂H₅)₄), ammonia, Si₂H₆, trimethylaluminum (TMA), tantalum ethoxide, Mo(CO)₆, Fe(CO)₅, and the like, or combinations thereof.

The flow rate of the gas-phase reactant may be at any desired rate. In an exemplary embodiment, the flow rate of the gas-phase reactant may be from about 0.1 standard cubic centimeters per minute (sccm) to about 10,000 sccm, preferably from about 0.5 sccm to about 90 sccm, more preferably from about 1 sccm to about 80 sccm.

The thickness of the coating formed on the nanoparticles may be of any desired thickness. In an exemplary embodiment, the thickness of the coating is from about 1 nanometer (nm) to about 100 nm, preferably from about 2 nm to about 90 nm, more preferably from about 3 nm to about 80 nm.

In one embodiment, the coating on the surface of the nanoparticles may include an organic material such as amorphous carbon. In one embodiment, the coating on the surface of the nanoparticles may include an inorganic compound such as an inorganic oxide.

In one embodiment, sodium chloride nanoparticles may be coated with amorphous organic coatings. In one embodiment, aluminum nanoparticles may be coated with amorphous organic films. In one embodiment, silicon nanocrystals may be coated with dense organic monolayers. In one embodiment, magnetic iron oxide nanoparticles may be coated with inorganic oxide layers, for example, silicon dioxide. In one embodiment, mixed oxides of yttrium and aluminum, doped with cerium may be coated with inorganic oxide layers or amorphous organic films.

The coating on the surface of the nanoparticles may be substantially continuous. This is in contrast to a film that appears clumped or globular. The substantially continuous coating does not appear patchy or variegated. In certain embodiments, the film is substantially continuous over at least 20%, preferably substantially continuous over at least 30% or 40%, more preferably substantially continuous over at least 50% or 60% and most preferably substantially continuous over at least 70% or 80% of the surface of the nanoparticles.

### Radiation Sources

Although the embodiments described herein exemplify ultraviolet radiation sources, such as vacuum ultraviolet radiation sources, other radiation sources may also be used, for example, x-ray, e-beam, visible, infrared radiation sources, or combinations thereof.

In one embodiment, one source of ultraviolet radiation is employed in the coating reactor. In one embodiment, two or more sources of ultraviolet radiation are employed in the coating reactor. In one embodiment, one source of ultraviolet radiation is used in the coating reactor and another source of ultraviolet radiation is used in a second reactor, where the nanoparticles that were exposed to the gas-phase reagent in the coating reactor are exposed to radiation from the second source of ultraviolet radiation, but without the addition of the coating reactant.

The ultraviolet radiation may be of any desired wavelength with the ultraviolet spectrum. In an exemplary embodiment, the ultraviolet radiation is from about 80 nm to about 400 nm, preferably from about 100 nm to about 200 nm, and more preferably from about 120 nm to about 180 nm.

In one embodiment, Xe₂* excimer lamp is used. In one embodiment, an Ar₂* excimer lamp (USHIO model UER20H-126), which operates at 126 nm is used. In one embodiment, both the Xe₂* excimer lamp and the Ar₂* excimer lamp are used. Both of these lamps generate radiation employing a dielectric barrier discharge, with a modest power input of 100 W. The output intensities equal 50 and 25 mW·cm⁻², respectively, for the Xe₂* and Ar₂* lamps, with full-width at half-maximum bandwidths equal to 14 nm and 10 nm, respectively.

### Coating Reactor

The coating reactor may be operated at any desired temperature. In an exemplary embodiment, the coating reactor may be operated at from about—100° C. to about 600° C., preferably from about room temperature to about 500° C. In one embodiment, the coating reactor is operated at about room temperature or about 23° C. In one embodiment, the coating reactor is operated from about room temperature to about 300° C. In one embodiment, the coating reactor is operated at about 450° C.

The coating reactor may be operated at any desired pressure. In an exemplary embodiment, the coating reactor may be operated at from about 0.5 kPa to about 500 kPa, preferably from about 25 kPa to about 150 kPa, and more preferably from about 40 kPa to about 120 kPa.

### Optional Purge Gas

One or more optional purge gases may be use in the methods described herein. The optional purge gas may include, for example, any inert gas such as nitrogen, helium, neon, argon, krypton, xenon, radon, and the like, or combinations thereof.

The optional flow rate of the optional purge gas may be at any desired rate. In an exemplary embodiment, the optional flow rate of the optional purge gas may be from about 0.1 standard cubic centimeters per minute (sccm) to about 50,000 sccm, preferably from about 20 sccm to about 20,000 sccm, more preferably from about 50 sccm to about 10,000 sccm.

The following Examples are intended to illustrate the above invention and should not be construed as to narrow its scope. One skilled in the art will readily recognize that the Examples suggest many other ways in which the invention could be practiced. It should be understood that numerous variations and modifications may be made while remaining within the scope of the invention.

### EXAMPLES

Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the invention are approximations, the numerical values set forth in the specific examples are reported as precisely as possible. Any numerical value, however, inherently contain certain errors necessarily resulting from the standard deviation found in their respective testing measurements.

### Example 1

### Amorphous Carbon Coatings on Sodium Chloride and Aluminum Nanoparticles

### Introduction

Photoinduced chemical vapor deposition (photo-CVD) was used to grow amorphous carbon coatings on both sodium chloride and aluminum nanoparticles. The aerosol of nanoparticles mixed with the reactant in vapor phase. This mixture entered a room-temperature, atmospheric-pressure cell, where the mixture was exposed to 172 nm radiation from a Xe₂* excimer lamp. Several coating reactants were investigated including, for example, methyl methacrylate (MMA). Tandem differential mobility analysis (TDMA) was used to determine coating thickness for nanoparticles of well-defined sizes. Parametric studies on coating thickness for both sodium chloride and aluminum nanoparticles were conducted, which include coating reactant flow rate, ultraviolet (ultraviolet) intensity, bare particle concentration, and initial particle size. Characterization by methods such as transmission electron microscope (TEM) and Fourier transform infrared (FTIR) spectroscopy was performed for morphology and composition analysis of coated nanoparticles.

Due to the highly pyrophoric property of aluminum particles, especially when the particles are in the nanoscale size range, the particles need to be isolated from contact with air. Partially oxidizing the particles to form a thin alumina layer at the surface is one easy and common way to accomplish this, as the oxide layer can inhibit further diffusion of oxygen, thereby maintaining the aluminum core. However, from the viewpoint of potential applications for the aluminum nanoparticles, for example, solid propellants, a drawback of this approach is that the oxide layer is a barrier to reaction, as the oxide layer should crack open before combustion cart occur. An alternative approach is to coat the particles with a non-oxide passivating layer, such as an amorphous carbon shell, that can serve as a diffusion barrier to oxygen until the shell is burned off.

A common technology for coating nanoparticles involves wet treatment. This is achieved by dispersing coating particles in a solvent containing reactive precursors. However, coatings obtained using liquid-phase routes normally involve collection of the particles followed by several expensive and complicated unit operations such as filtration, washing, drying, and waste stream treatment. Especially when particles in the dry form are needed for the end use, wet coating becomes less attractive. Gas phase process is one example of the alternative approaches that have been developed for particle coating.

Photoinduced chemical vapor deposition can be used to deposit thin films in both gas and liquid media. Gas phase photoinduced chemical vapor deposition methods have all the advantages of gas-phase coating methods mentioned above. They also can be applied at room temperature and atmospheric pressure, with minimized thermally induced damage in the film. Most of other gas-phase coating methods need either high temperature or high vacuum systems to produce coatings.

In the photoinduced chemical vapor deposition process, excimer lamps provide high-intensity, narrow-band, incoherent radiation with efficiencies up to 40%. The photons generated by excimers decompose the reactant to generate radicals, which react with the surface to grow a film. Each excimer radiates at a particular wavelength. Lamps of XeCl* (308 nm), KrCl* (222 nm), Xe₂*(172 nm), Kr₂*(146 nm), and Ar₂*(126 nm) have been used, of which KrCl*, Xe₂* and Ar₂* with photon energies of 5.6, 7.2 and 9.85 respectively, are the most widely used ones.

### Design and Implementation of Experimental System

Due to its advantages as a gas-phase coating method, photoinduced chemical vapor deposition was applied to deposit thin films on nanoparticles. Aluminum particles in the size range of about 5 to about 100 nm were synthesized using thermal plasma. Naturally formed aluminum oxide coating is a barrier for combustion when aluminum nanoparticles are used in energetic materials, such as solid propellant. Alternative coatings, such as amorphous carbon films, can be used so that the formed shell can both protect the inner aluminum core and be easily oxidized if ignited. Thus, bare aluminum nanoparticles are treated as the cores for the coating study. Meanwhile, sodium chloride nanoparticles were used to study the amorphous carbon coatings. Sodium chloride particles are easily aerosolized and provide a system for performing experiments to study photoinduced chemical vapor deposition.

Tandem differential mobility analysis was used to determine coating thickness of nanoparticles of well-defined sizes, in which aluminum nanoparticles produced in the thermal plasma reactor were used as an example. Aluminum nanoparticles exiting the plasma reactor were sampled and diluted by an onstage N₂ ejector through a sampling probe. For the studies of sodium chloride nanoparticles, the particles were aerosolized from solution using a nebulizer followed by a dryer, with N₂ as the carrier gas. In either case, the sample was charged in either a unipolar charger or a bipolar diffusion charger, and entered the first differential mobility analyzer (DMA1), which selected a narrow slice from the particle size distribution, at a mobility diameter Dp that is specified by setting the differential mobility analyzer voltage. These size-selected nanoparticles, carried in room-temperature nitrogen, were mixed with a vapor-phase coating reactant before entering the coating reactor, where they were exposed to 172 nm radiation from a Xe₂* excimer lamp (USHIO model UER20H-172, USHIO AMERICA, INC., Cypress, Calif., USA) at a pressure close to one atmosphere. The lamp, which is cylindrical, was mounted end-on to the flow tube. The lamp output was collimated by a CaF₂ lens, forming a beam that filled the flow tube. The lens was kept clean of particles by a purge flow of argon.

Aerosol exiting the coating reactor was delivered to a second differential mobility analyzer (DMA2). This, in series with an ultrafine condensation particle counter, provided on-line measurements of the particle size distribution. By comparing measurements of the size distributions with and without addition of the coating reactant, the increase in size (coating thickness) of the nanoparticles during the coating process was determined.

### Coated Sodium Chloride Nanoparticles

The feasibility of using photoinduced chemical vapor deposition to coat nanoparticles with controllable thickness was examined by depositing amorphous carbon films on sodium chloride nanoparticles. With the ease of production with stable concentration and the inertness to the coating reactants, aerosolized sodium chloride particles provide a convenient test system for performing experiments to study photoinduced chemical vapor deposition.

### Photoinduced Homogeneous Nucleation

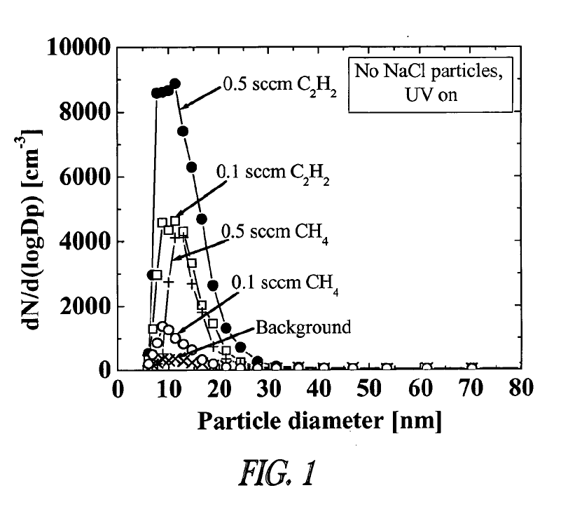

One effect that can potentially compete with photoinduced chemical vapor deposition is photoinduced nucleation of particles from the coating reactant. The possible occurrence of photoinduced nucleation was tested for each coating reactant by running experiments where the coating reactant, without nanoparticles, was introduced into the coating reactor with the excimer lamp turned on. FIG. 1 shows the results for CH₄ and C₂H₂, using 0.1 sccm and 0.5 sccm for each of them. Photoinduced nucleation was observed at both flow rates for both gases, they all produced a peak value about 10 nm in the size distributions. At the same flow rate, carbon particles by photoinduced nucleation showed higher concentration for C₂H₂ than for CH₄, and higher flow rate produced more carbon particles for both gases. Due to the fact that CH₄ is essentially transparent to 172 nm radiation, it is believed that the observed photoinduced nucleation for CH₄ may be due to gas-phase leakage, such as oxygen, which is very sensitive to ultraviolet radiation.

Based on these results, coating experiments were run by introducing sodium chloride particles at a size much bigger than 10 nm, either 30 nm or 40 nm. This may help to discriminate the size distributions between photoinduced nucleation and the particles introduced for coating, so as to minimize the effect of gas phase nucleation in interpreting the particle coating results.

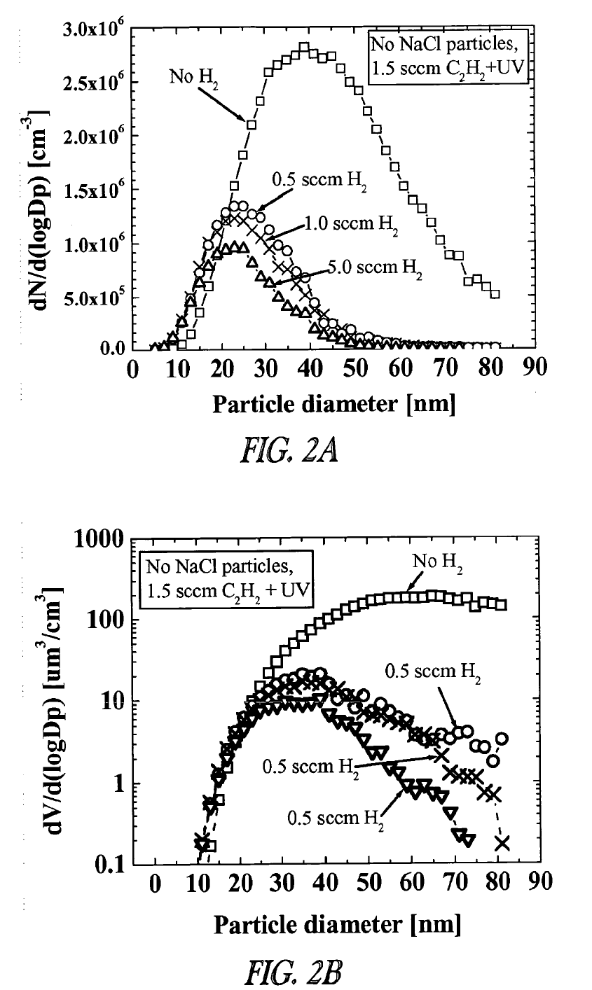

Due to the competition between photoinduced nucleation and particle growth by photoinduced chemical vapor deposition, the gas phase nucleation from ultraviolet radiation is generally undesired. It may also bring unwanted particles existing as contaminant for produced coatings. Hydrogen can be used to consume carbon atoms by forming gaseous hydrocarbon products, such as methane, so as to suppress the formation of carbon particles formed by photoinduced nucleation. FIG. 2 shows the measured size distributions for particles produced by gas phase nucleation, when 1.5 sccm C₂H₂ was injected with ultraviolet turned on and various flow rates of hydrogen introduced. As can be seen, even small flow rate of hydrogen effectively decreased the concentration of the carbon particles. With the use of hydrogen, the concentrations of larger carbon particles dropped dramatically, while the smaller carbon particles (<20 nm) were less affected. While not being bound by theory, it is believed that when no hydrogen is introduced, the number of nucleated particles is much greater, causing more growth by coagulation, which leads to the formation of larger particles. When hydrogen is injected, nucleation is suppressed by the increased formation of noncondensible hydrocarbon in the gas phase. Decreased number of nucleated particles leads to decreased particle growth by coagulation and decreased total particle concentration. FIG. 2 also shows the volume distribution of the particles measured for each case. The relative total volume concentrations are shown in Table 1, where the volume concentration for each case was divided by that of the case when no hydrogen was introduced. These results indicate that hydrogen affects photoinduced nucleation by apparently decreasing the concentration of larger particles.

The ways that can be applied to suppress photoinduced nucleation also include the use of appropriate coating reactants, such as those which are less prone to photoinduced nucleation, decreasing the ultraviolet intensity, and using an appropriate range of reactant flow rates.

TABLE 1
Relative total volume concentrations for the size distributions
shown in FIG. 2

| Case | 0.5 sccm H₂ | 1.0 sccm H₂ | 5.0 sccm H₂ |
|---|---|---|---|
| Relative total volume | 11.6% | 10.0% | 5.9% |
| concentration (%) | | | |

### Particle Coating Using Different Precursors

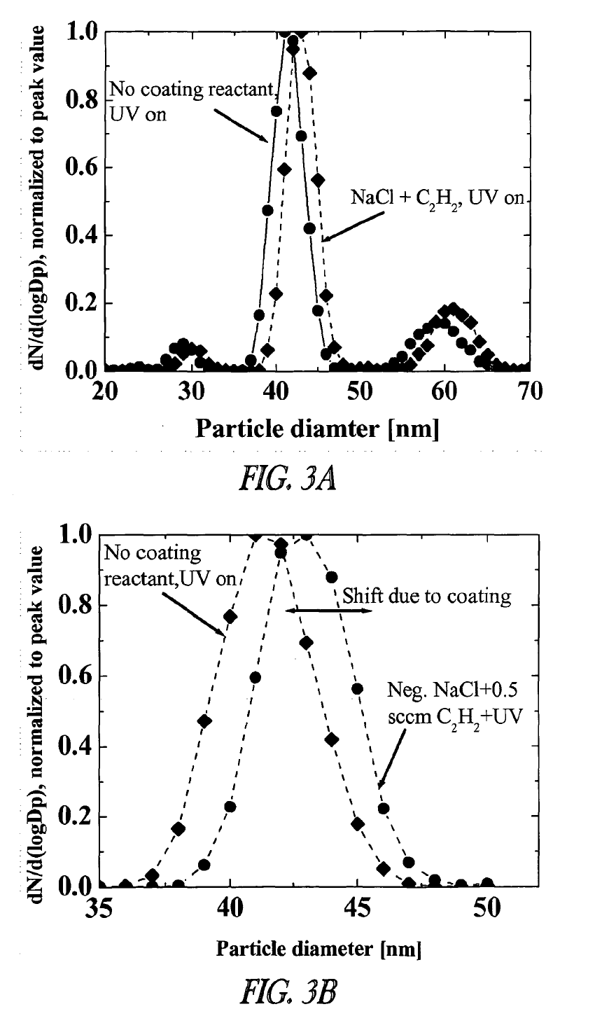

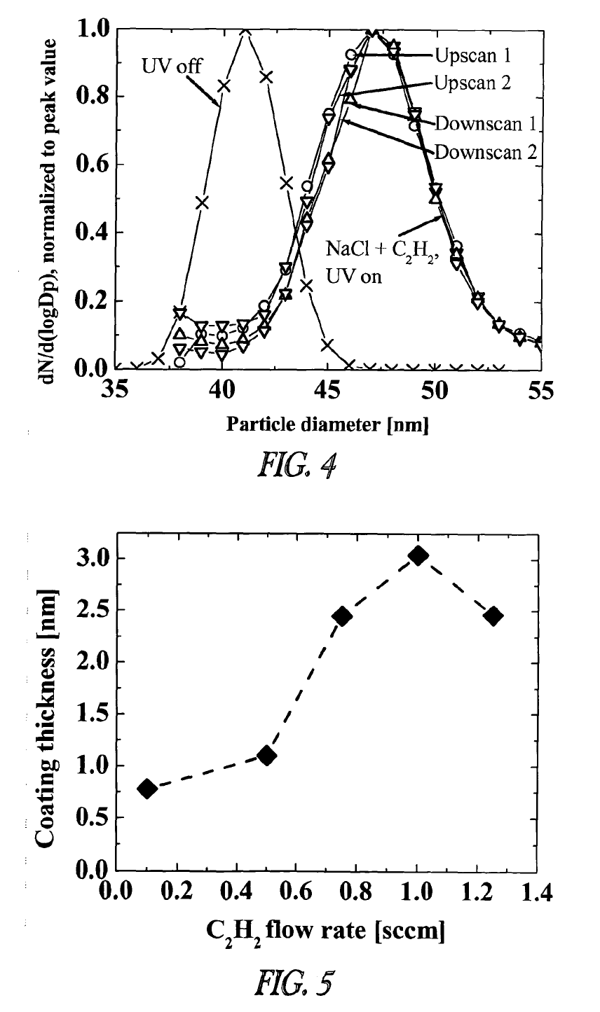

The tandem differential mobility analysis measurements studying the effect of reactant flow rate on particle coating thickness were begun by using C₂H₂ as the reactant. For the case of 0.5 sccm of C₂H₂, particle size distributions from FIG. 2 were normalized to their peak values, and are shown in FIG. 3. It is evident that the distribution shifted to larger sizes by about 2 nm compared to that for the bare particles, with nearly the same value for the full-width-at-half-maximum for the distribution of about 5 nm. In FIG. 3, it is seen that the satellite peaks also shifted during the coating process to larger values by about 2 nm. While not being bound by theory, it is believed that these results suggest that essentially all of the sodium chloride nanoparticles were coated. These results also indicated that the coating process by photoinduced chemical vapor deposition was well-behaved in that all the featured peaks shifted correspondingly, and that, tandem differential mobility analysis measurement is an effective tool to interpret the coating process. Once the particle concentration introduced into the coating reactor was stable, and the tandem differential mobility analysis system was well adjusted, size distribution measurements obtained from tandem differential mobility analysis were found to be virtually unchanged from day to day. FIG. 4 shows the results of experiments conducted at different times (several minutes apart) where 1 sccm of C₂H₂ was mixed with 41 nm sodium chloride particles when the ultraviolet lamp was on and off. For the particles coated, the size distributions were continuously measured and both up scan (increasing differential mobility analyzer voltages to scan from smaller to larger particles) and down scan (decreasing differential mobility analyzer voltages to scan from larger to smaller particles) of the DMA2 were taken. The peaks in the size distributions in all four scans were at about 47 nm, and the scans were virtually superimposable, demonstrating the reproducibility of the measurement.

Besides C₂H₂, several other coating reactants were investigated, including, for example, CH₄, C₂H₄, C₂H₆, styrene, and methyl methacrylate (MMA). The gaseous reactants were directly introduced into the coating reactor. The liquid reactants such as styrene and methyl methacrylate were vaporized using a bubbler and delivered into the reactor with nitrogen as the carrier gas. All of the coating reactants, with the exception of C₂H₄, produced measurable particle growth due to photoinduced chemical vapor deposition. However, for CH₄, C₂H₆ and styrene these increases were small, corresponding to coating thicknesses of about 1 nm, and were unaffected by the reactant flow rate. FIG. 5 shows the measured coating thickness for various C₂H₂ flow rates. As can be seen, the coating thickness increased to about 3 nm as the C₂H₂ flow rate increased, until declining as the flow rate increased above about 1 sccm. While not being bound by theory, it is believed that the decline is likely due to the competition with gas phase nucleation.

Besides the possibility to produce carbon particles by gas phase nucleation from C₂H₂ and CH₄ (see, e.g., FIG. 1), among the reactants tested, it was found that styrene was prone to photoinduced nucleation, generating high particle concentrations (greater than 10⁵ cm⁻³) at flow rates as low as 0.004 sccm. On the other hand C₂H₄, C₂H₆ and methyl methacrylate showed no tendency to undergo photoinduced nucleation, except, in the case of methyl methacrylate, at much higher flow rates (>12.8 sccm) than were needed to coat nanoparticles.

### Parametric Study Using Methyl Methacrylate as the Coating Precursor

Among the coating reactants investigated, some of them may be difficult to produce a controllable coating thickness (e.g., CH₄, C₂H₆, and styrene); some may be sensitive to photoinduced nucleation (e.g., styrene); some may not be able to generate measurable particle growth (e.g., C₂H₄). C₂H₂ was found to generate considerable high concentration of carbon particles by photoinduced nucleation at low flow rates. The coating thickness measurements for various C₂H₂ flow rates produced an increase-peak-decrease trend, with a maximum coating thickness of about 3 nm at a flow rate of 1 sccm. Methyl methacrylate was found to be the most promising coating precursor among the reactants tested. A monotonic trend for coating thickness versus reactant flow rate was produced using methyl methacrylate. No noticeable particles due to photoinduced nucleation were observed until a high methyl methacrylate flow rate (12.8 sccm) was used, which is much higher than the flow rates that were needed for particle coating with relatively thick films. Thus, the parametric studies using methyl methacrylate as the coating reactant are reported.

### Effect of Methyl Methacrylate Flow Rate

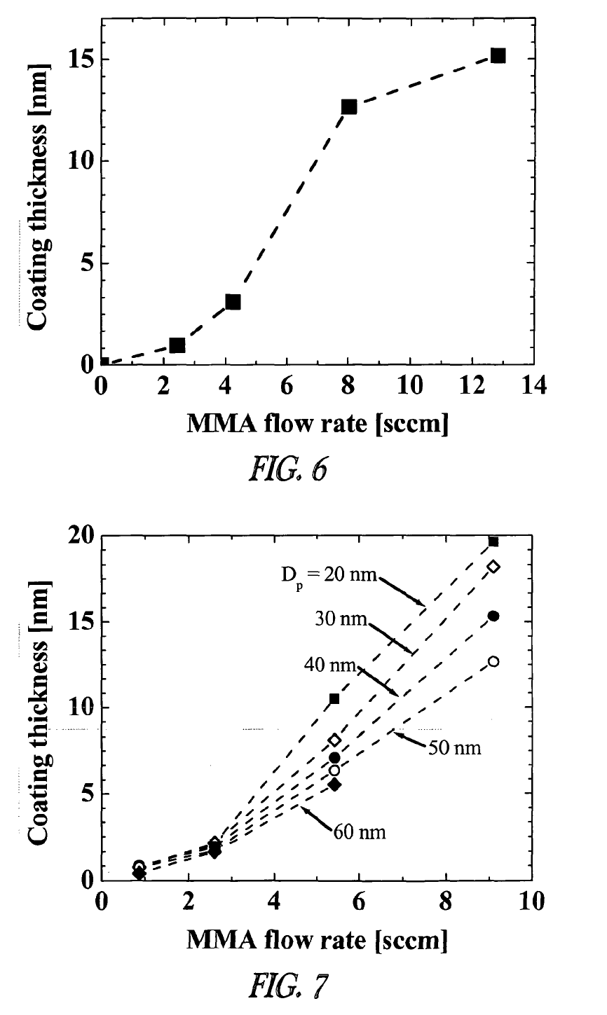

FIG. 6 shows the measured coating thickness for various methyl methacrylate flow rates, for 40 nm sodium chloride particles. No gas phase nucleation was detected for methyl methacrylate in the range of flow rates shown here. Thus, no competition between particle growth and photoinduced nucleation was expected. Methyl methacrylate gas contained in a bubbler was carried by nitrogen as the carrier gas and delivered into the reactor at room temperature. The methyl methacrylate flow rate was calculated based on the flow rate of the nitrogen carrier gas.

The observed coating thickness increased monotonically with increasing methyl methacrylate flow rates. A wide range of coating thickness up to 15 nm was achieved. When other parameters such as ultraviolet radiation intensity and coating reactor pressure were fixed, the monotonic relationship between the coating thickness and methyl methacrylate flow rate implies that particle growth by photoinduced chemical vapor deposition can be well controlled by varying the reactant flow rate. Each of the data points in the figure represents the average of several tandem differential mobility analysis size distribution scans.

### Effect of Initial Particle Size

Sodium chloride particles with diameters ranging from 20 nm to 60 nm were coated using different various flow rates of methyl methacrylate. Coating thickness for a given initial particle size, for increasing flow rates of methyl methacrylate, increased monotonically from sub-nm to 20 nm (see, e.g., FIG. 7).

The coating thickness of a particle in a supersaturated vapor is determined by the initial size of the particle, more precisely by the Knudsen number of the particle, Kn=2λ/Dₚ. In the previous relation, mean free path for collisions between molecules in the gas is denoted by λ and particle diameter by Dₚ. For particles in free molecule regime (Kn>10) the particle growth rate is independent of particle size. For particles in continuum regime (Kn<0.1) the growth rate is inversely proportional to the diameter of the particle. The relationship between particle growth and particle size becomes complicated for particles in transition regime (0.1<Kn<10), and the growth rate is expected to decrease with increasing particle size, but slower than 1/Dp.

As the methyl methacrylate flow rate used is a small fraction of the argon and N₂ flow rate (about 1/1000), it is believed that the residence times are not affected by methyl methacrylate flow rate. Thus, coating thickness increase is virtually proportional to particle growth rate. For the experiments conducted, all the particle sizes lie in the transition regime (Kn varying from 1.75 to 6.2) as the mean free path about 62 nm for the Ar—N₂ mixture in the coating cell at local room temperature and atmospheric pressure. At a fixed methyl methacrylate flow rate, coating thickness for the particles decreases with increase in diameter, as shown in the FIG. 7, but the decline is slower than 1/Dp, which is expected from theory because the particles are in the transition regime.

### Effect of Ultraviolet Intensity

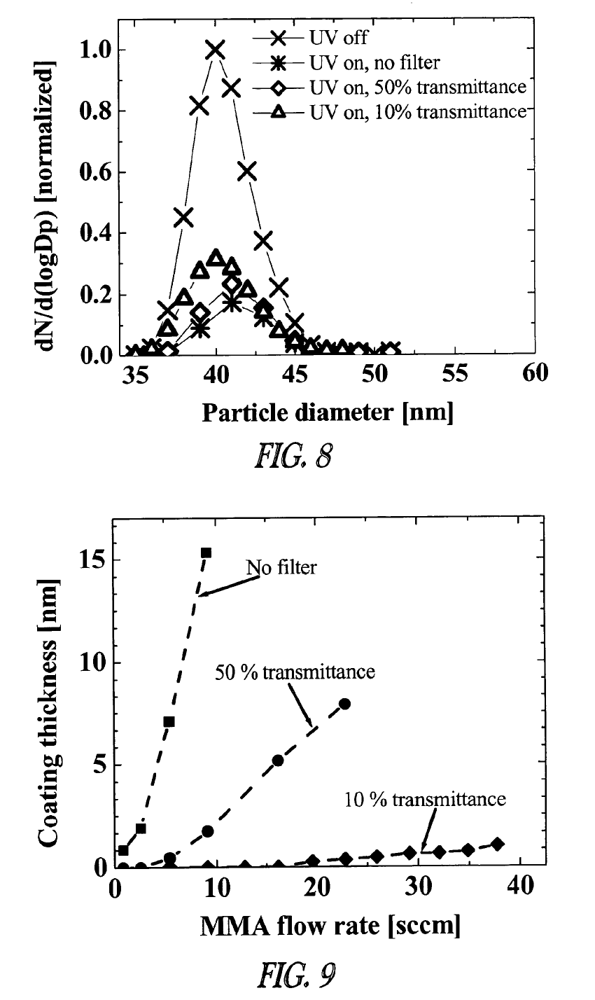

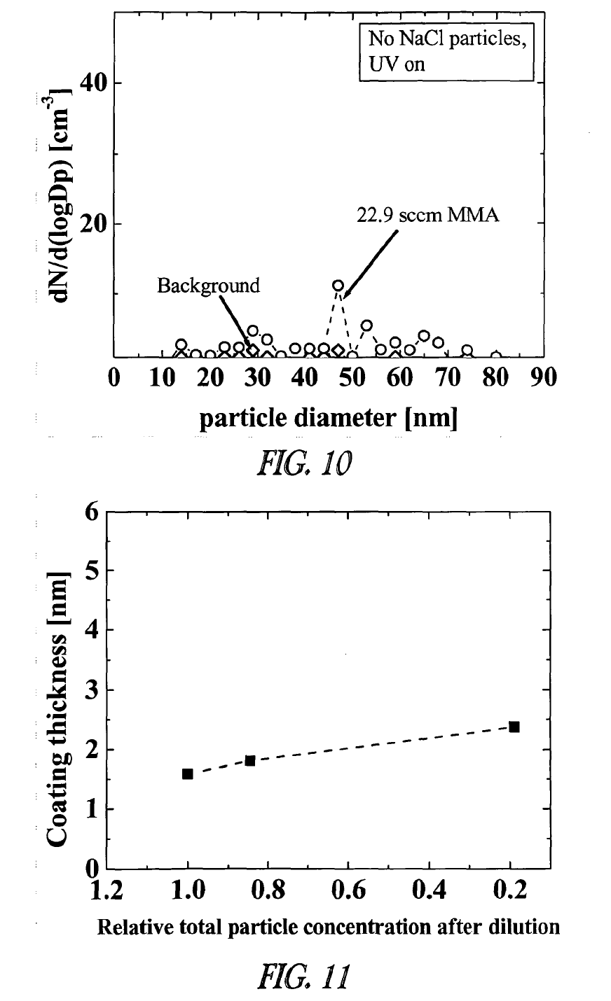

Ultraviolet radiation intensity apparently affected the charge status of particles (cf., FIG. 8), where two ultraviolet radiation neutral density MgF₂ bandpass filters were used, with transmittances of about 50% and about 10%, respectively, over the wavelength range about 122-200 nm. The same two filters were used here, to explore the effect of ultraviolet radiation intensity on coating thickness. Preselected 40 nm sodium chloride particles were introduced as the core particles. The measured coating thicknesses versus methyl methacrylate flow rates with various ultraviolet radiation intensities are shown in FIG. 9. Ultraviolet radiation intensities were regulated with the use of the two filters with different transmittances. FIG. 9 shows that ultraviolet radiation intensity, as expected, greatly affected the particle growth by photoinduced chemical vapor deposition. Lower ultraviolet radiation intensity (i.e., lower transmittance of the filter) implied a smaller flux of photons passed through the ultraviolet radiation window. Consequently, fewer radicals produced by photo-dissociation were expected, which resulted in smaller values of the coating thickness.

Meanwhile, as seen from FIG. 9, larger values of slopes of the growth curves for higher ultraviolet radiation intensities were found, indicating that particle growth by photoinduced chemical vapor deposition was more sensitive to methyl methacrylate flow rate for higher ultraviolet radiation intensities. For the excimer lamp used with narrow spectra distribution of ultraviolet radiation intensity, each photon has almost the same energy (7.2 eV). Thus, ultraviolet radiation intensity is proportional to photon flux. A 50% decrease of the ultraviolet radiation intensity implies a 50% decrease of the photon flux passed through the ultraviolet radiation window. However, gas phase reaction and surface reaction are both volumetric during photoinduced chemical vapor deposition, and photon flux exponentially decreases along the coating reactant zone. Thus, it is believed that the relationship between coating thickness and ultraviolet radiation intensity at a fixed methyl methacrylate flow rate is not expected to be linear. The curves measured here supply useful information to investigate the mechanisms for photoinduced chemical vapor deposition of nanoparticles, as well as the relative propensities for nucleation versus particle coating.

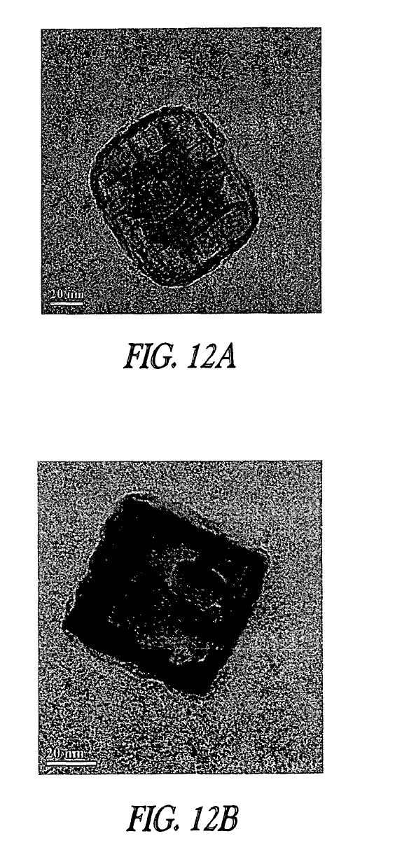

At high enough precursor flow rates the radicals from photo-dissociation can form carbon particles by gas phase nucleation. Particle growth by photoinduced chemical vapor deposition has to compete with photoinduced nucleation. When ultraviolet radiation intensity is decreased with the use of filter, which leads to fewer radicals, it is expected to suppress gas phase nucleation. FIG. 10 shows the measured size distributions of background and the particles from photoinduced nucleation when the filter with 50% transmittance and 22.9 sccm of methyl methacrylate were used. The concentration at each particle size was comparable to that of the background, indicating that no noticeable particles were produced. The tendency to undergo gas phase nucleation was verified in the non-filter case with the methyl methacrylate flow rate higher than 12.8 sccm. No photoinduced nucleation was observed here, using the 50%-transmittance filter, for methyl methacrylate flow rates up to 22.9 sccm. When the filter with 10% transmittance was used, at a flow rate of methyl methacrylate as high as 37.8 sccm, no tendency to undergo photoinduced nucleation was observed. The coating thickness (for 37.8 sccm of methyl methacrylate and 10% transmittance of filter) was about 1 nm.

### Effect of Core Particle Concentration

To study the effect of particle concentration on coating thickness, an experiment with various sodium chloride particle concentrations and fixed methyl methacrylate flow rate was conducted. Different flow rates of nitrogen were introduced downstream of the nebulizer to dilute the sodium chloride particles produced. The size distribution of sodium chloride particles with each flow rate of nitrogen dilution gas was measured and the corresponding total particle concentration was calculated by integrating the size distribution. For each dilution gas flow rate, the total particle concentration was divided by the concentration when no dilution gas was used. Thus, each dilution gas flow rate was converted into a relative total particle concentration. A relative total particle concentration equal to 1 indicates that there was no dilution, and lower values implied higher dilution ratio. The methyl methacrylate flow rate was fixed at 2.44 sccm, and 40 nm sodium chloride particles were selected as the core particles.

FIG. 11 shows the measured coating thickness for various relative total particle concentrations after dilution. A small increase of coating thickness with increasing dilution ratio was obtained, suggesting a possible role for radiation attenuation by particle absorption.

FIG. 11 also shows that the dependence of coating thickness on dilution effect is much weaker than that on methyl methacrylate flow rate (cf, FIG. 6). After being selected by DMA1, the particle concentration entered into the coating reactor is expected to be sufficiently low, relative to the radical concentration. In this “diluted aerosol” regime, according to the theory of condensation growth, the growth rate depends on the saturation ratio, which is the methyl methacrylate flow rate at fixed ultraviolet radiation intensity. Also due to the low concentration of the core particles introduced into the coating reactor, the effect of the increased effective methyl methacrylate flow rate by particle dilution is small. Thus, increased dilution ratio of core particles produced small increase of coating thickness, indicating a much weaker effect than that of methyl methacrylate flow rate.

### Characterization of Coated Particles

Morphology analysis of coated sodium chloride particles was conducted with transmission electron microscopy (TEM). The flow rate of methyl methacrylate introduced into the coating reactor was 9.1 sccm. The particles selected with mobility diameter of about 41 nm were collected on a SiO/SiO₂ coated copper transmission electron microscopy grid (Ted Pella Inc., Redding, Calif., USA) using an electrostatic sampler biased at −3.0 kV. Transmission electron microscopy grids were located downstream of the coating reactor. Images were obtained using a Tecnai T12 microscope (FEI Company, Hilsboro, Oreg., USA) operating at an accelerating voltage of 120 kV.

FIG. 12 shows representative transmission electron microscopy images of mobility selected 41 nm sodium chloride particles collected downstream of the coating reactor with and without reactant introduced. FIG. 12(a) indicates that the bare particle measured about 60 nm across. It is believed that this represents a particle that exited DMA1 as a doubly-charged 59 nm particle for which the mobility diameter is identical to that of a singly-charged 41 nm particle. Compared to the bare sodium chloride particle, the image of FIG. 12(b) confirms the existence of an amorphous coating layer. It shows an apparent coating layer with the thickness about 5 nm. However, since sodium chloride particles are partially vaporized by the high energy electron beam under transmission electron microscopy, it is difficult to define the interface between the core and the coating shell. This may explain the discrepancy between the coating thicknesses inferred from the tandem differential mobility analysis measurements and the transmission electron microscopy image.

The surface composition of methyl methacrylate-coated particles was examined with Fourier transform infrared (FTIR) spectroscopy. Samples were collected by inertial impaction onto stainless steel mesh filters, located downstream of the coating reactor, for 4 hours and were studied using diffuse reflectance Fourier transform infrared spectroscopy (DRIFTS). To collect enough particle samples for diffuse reflectance Fourier transform infrared spectroscopy, the preselection step was omitted (i.e., the particle streams bypassed DMA1), and the experiment was conducted under high flow rate conditions (methyl methacrylate=9.1 sccm). Spectra of the collected particle samples were obtained at 2 cm⁻¹ resolution with 32 scans using a Nicolet Magna-IR 750 spectrometer equipped with a diffuse reflectance accessory from Harrick Seagull (Ossining, N.Y., USA).

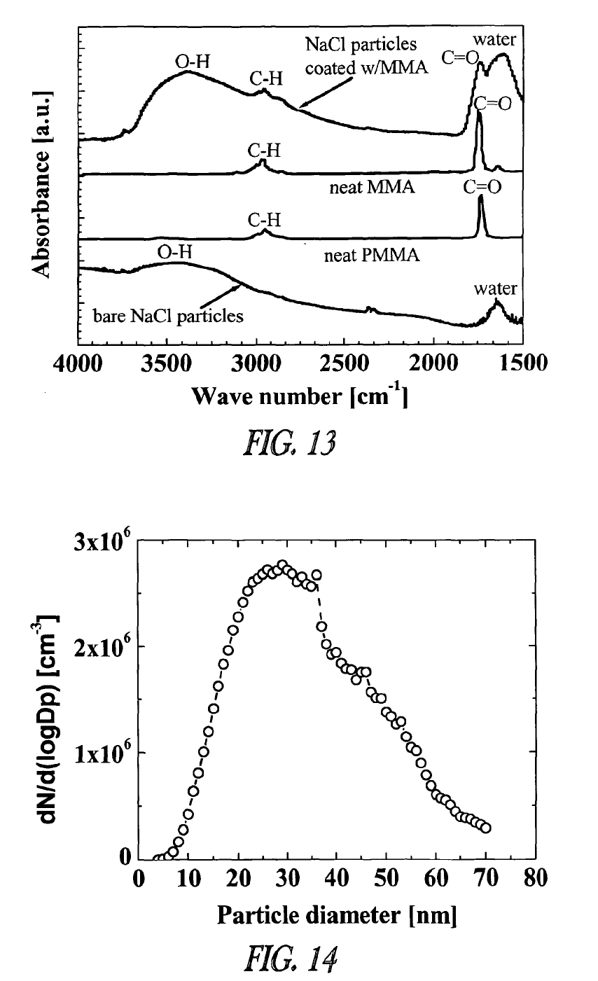

FIG. 13 shows two representative spectra of the sodium chloride particles, one of bare particles and one of coated particles. The spectra of neat methyl methacrylate and polymethyl methacrylate are also included. In addition to the peaks ascribed to water and OH (sodium chloride readily absorbs water during sample preparation), the spectrum for the coated particles shows the broad C—H stretching band in the 2900-3000 cm⁻¹ region, and the C═O band at 1740 cm⁻¹, that are both clearly attributable to the coating by methyl methacrylate.

### Coating Study Using Aluminum Nanoparticles

Photoinduced chemical vapor deposition nanoparticle coating was also examined on aluminum nanoparticles synthesized by DC thermal plasma. The same coating reactor with the tandem differential mobility analysis setup as used for sodium chloride was used for aluminum particles. The coating cell followed by tandem differential mobility analysis was implemented downstream of the DC thermal plasma reactor. The tandem differential mobility analysis system was operated at atmospheric pressure. Thus, the water-ring pump, which was applied to keep the pressure of the plasma reactor at 53 kPa was not used here. Instead, the nitrogen ejector was applied to regulate the pressure of the plasma reactor to one atmosphere and sample the aluminum particles effectively into the coating cell. To keep the sampling line of the ejector cooled, 0.2 slm H₂ instead of 0.5 slm was used for the plasma gas. Counterflow was not incorporated in this study. The experimental parameters used for aluminum nanoparticle synthesis were as follows:
Plasma current: I=200 A
Plasma gases: Ar=30 slm, H₂=0.2 slm
Chamber pressure: P_{chamber}=100 kPa.

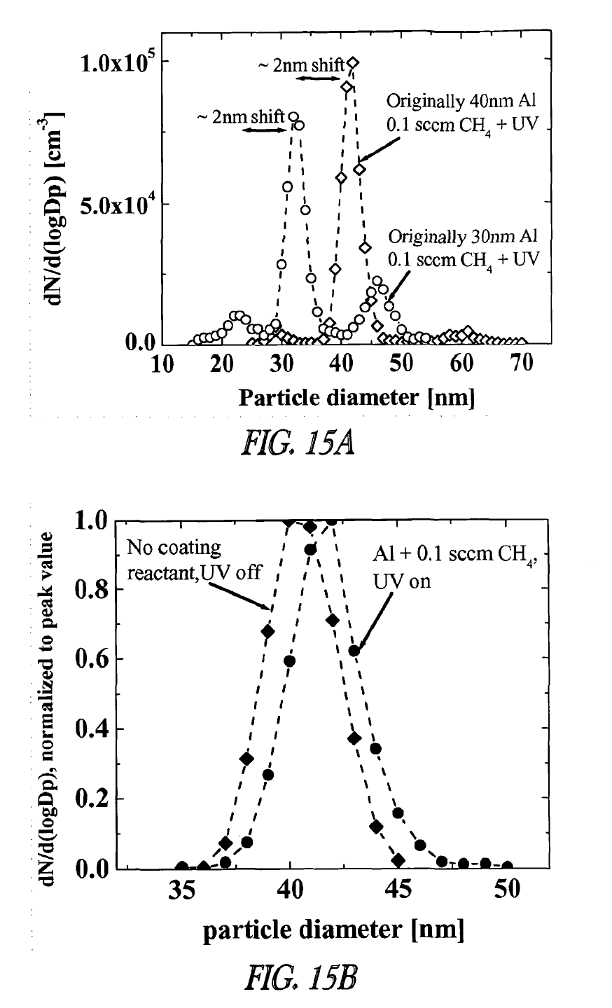

FIG. 14 shows the size distribution of aluminum particles synthesized by thermal plasma using the adjusted parameters. For the case of synthesis when the chamber pressure was 53 kPa and the flow rate of H₂ was 0.5 slm, the peak values of size distributions of the aluminum particles produced were smaller than 20 nm. The size distribution here indicates a larger peak value of about 29 nm.

### Particle Coating Using CH₄ and C₂H₂

CH₄ and C₂H₂ were used as the coating reactants to study photoinduced chemical vapor deposition on aluminum nanoparticles. FIG. 15 shows the size distributions of coated 30 nm and 40 nm particles with ultraviolet and 0.1 sccm CH₄ introduced (left). The size distributions normalized to peak value for 40 nm bare and coated particles were also included (right). As shown by FIG. 15, for both cases, the size distributions shifted to the right by about 2 nm as a result of the coating process. Various flow rates of CH₄ were also introduced. It was found that at the flow rates of CH₄ where the concentration of the carbon particles produced by photoinduced nucleation did not affect the interpretation of tandem differential mobility analysis measurement, a coating thickness of about 1 nm was observed and was not affected by the reactant flow rate.

Compared to CH₄, C₂H₂ is more prone to gas phase nucleation. It is relatively difficult to produce aluminum nanoparticles with long run time and stable concentration compared to sodium chloride nanoparticles. Small flow rates of C₂H₂ (<0.5 sccm) were examined with aluminum particles, and a weak trend of increasing coating thickness with increasing C₂H₂ flow rate was observed. For the higher flow rate of C₂H₂, a trend of increase-peak-decrease mode similar to the case of sodium chloride particles can be expected.

### Particle Coating Using Methyl Methacrylate

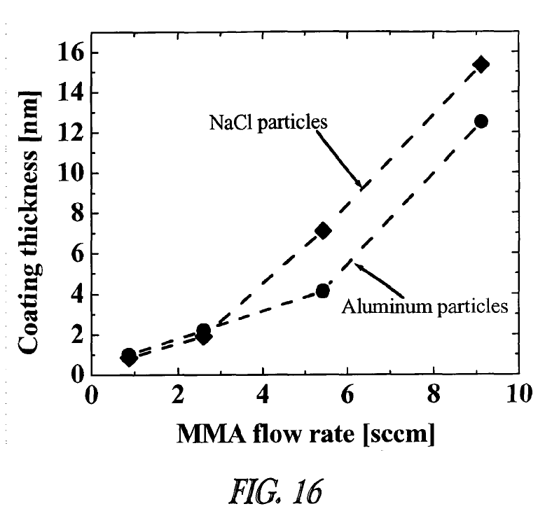

Similar to the coating study on sodium chloride particles using methyl methacrylate, a monotonic increasing trend for coating thickness versus reactant flow rate was observed when 40 nm aluminum particles were preselected, as shown in FIG. 16. The coating thicknesses with various methyl methacrylate flow rates for 40 nm sodium chloride particles are plotted for comparison. At higher methyl methacrylate flow rate (>5.4 sccm), thinner effective coating thicknesses existed with aluminum than with sodium chloride particles. Sodium chloride is essentially inert to coating materials such as carbon. The coating process starts with the first carbon layer attached on the sodium chloride surfaces, potentially with no interface formed between the first carbon layer and the surface of the core particle. In contrast, when hydrocarbon radicals meet aluminum particles, chemical reactions can be expected to occur. Carbon and hydrogen in the coating materials (and possibly oxygen, if present as an impurity) react with aluminum on the particle surface, leading to the formation of an interface layer. Incoming atoms or radicals keep diffusing through the interface layer, reacting with aluminum and forming another interface layer until no further diffusion is possible. Finally a structure of coating shell-interface-core particle is produced, and this process causes the crystalline aluminum core to shrink.

### Particle Coating Characterization

Coated aluminum particles were analyzed with transmission electron microscopy. The flow rate of methyl methacrylate introduced was 5.4 sccm. Particles selected with a mobility diameter of about 41 nm were collected on a SiO/SiO₂ coated copper transmission electron microscopy grid (Ted Pella Inc., Redding, Calif., USA) using an electrostatic sampler biased at −2.0 kV. Transmission electron microscopy grids were located downstream of the coating reactor. Images were obtained using a Tecnai T12 microscope (FEI Company, Hilsboro, Oreg., USA) operating at an accelerating voltage of 120 kV.

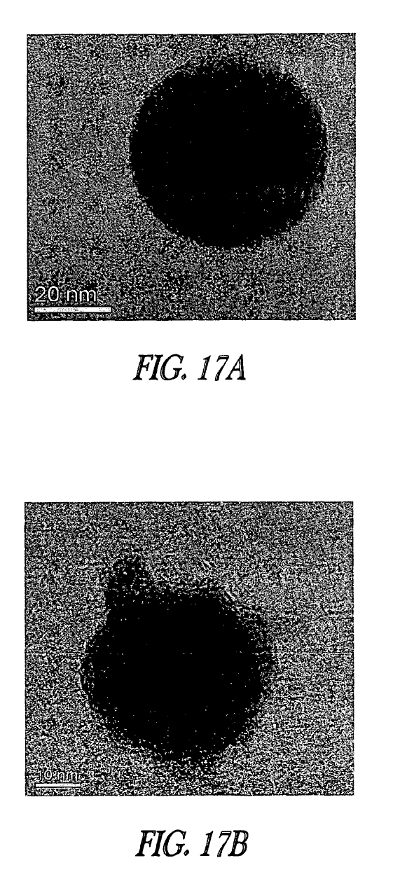

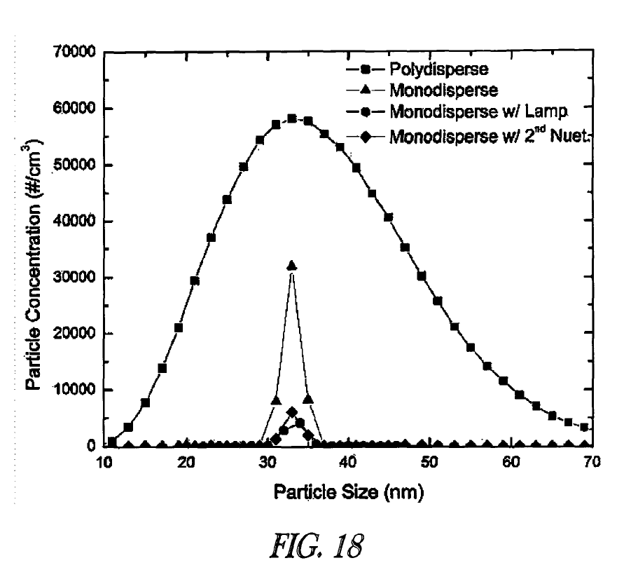

FIG. 17 shows transmission electron microscopy images of 41 nm preselected particles collected downstream of the coating reactor with and without methyl methacrylate introduced. The image on the left indicates that the bare particle measures about 60 nm across, representing a doubly-charged about 59 nm particle that exited of DMA1. The image on the right shows the existence of a coating layer, for a particle with a measured diameter about 43 nm. Due to the formation of the interface layer and the diffusion between aluminum and the atoms from the coating materials, it is difficult to precisely define the interface between the coating shell and the core here. For the use of 5.4 sccm methyl methacrylate flow rate, tandem differential mobility analysis measurement showed an effective coating thickness of about 4.1 nm, corresponding to about 48 nm particles. While not being bound by theory, it is believed that a possible reason for the discrepancy between the coating thickness inferred from the tandem differential mobility analysis measurements and the transmission electron microscopy image is that the particle shown in the transmission electron microscopy image was from the tail of the size distribution and is not representative.

### SUMMARY

Photoinduced chemical vapor deposition has potential advantages compared to other coating methods that have been used. As an initial study of the application of photoinduced chemical vapor deposition in nanoparticle coating, the feasibility of this new technology used to form amorphous carbon coating on sodium chloride and aluminum nanoparticles was demonstrated and examined.

Aerosolized nanoparticles were mixed with a vapor-phase coating reactant and were introduced into a room-temperature, atmospheric-pressure cell, where the mixture was exposed to 172 nm radiation from a Xe₂ excimer lamp. Tandem differential mobility analysis was used to study the coating process, including determining coating thickness for nanoparticles of well-defined sizes. The changes of bare particle charge status by photoemission were observed and analyzed. Two small satellite peaks appeared when ultraviolet was on, for both positively and negatively charged particles, due to the gain or loss of electrons of the particles. For negatively charged particles, they may be doubly charged out of DMA1, then lose electrons by photoemission and become singly charged. They may also be singly charged originally, attach electrons and become doubly charged. For positively charged particles, a similar hypothesis can be used to explain the existence of the satellite peaks, For both particles of both polarities, a considerable drop in apparent particle concentration was found, due to particle neutralization in the coating reactor.

Ultraviolet intensity was verified to have a great effect on particle charge by using bandpass filters with different transmittances in the specific wavelength range of the lamp. Lower ultraviolet intensity changed particle charges less. Ultraviolet photons can dissociate coating reactants into radicals, and may charge these radicals to ions. When coating reactants were introduced, there was a further apparent reduction of the particle concentration. This suggests that either the growth of a carbon coating on the particles increases their quantum efficiency with respect to photoemission, or that the ions from photoionization or photodissociation of the coating reactants have attached to some of the oppositely charged particles.

One effect that can potentially compete with photoinduced chemical vapor deposition is photoinduced nucleation of particles from the coating reactant. The occurrence of photoinduced nucleation was tested for each coating reactant by running experiments where the coating reactant, without core nanoparticles, was introduced into the coating reactor with the excimer lamp turned on. Several coating reactants were investigated, including CH₄, C₂H₂, C₂H₄, C₂H₆, styrene and methyl methacrylate (MMA). Among the gases tested, it was found that styrene was by far the most prone to photoinduced nucleation. C₂H₂ also produced considerable high concentration of carbon particles from gas phase nucleation at low flow rates. As CH₄ is essentially transparent to 172 nm radiation, nucleation observed may have been initiated by photo-dissociation of impurity oxygen in the coating cell, creating O or OH radicals that then reacted with the CH₄. In contrast, C₂H₄, C₂H₆ and methyl methacrylate showed no tendency to undergo photoinduced nucleation, except for methyl methacrylate at high flow rates (>12.8 sccm). Hydrogen was found to be able to effectively suppress photoinduced nucleation in C₂H₂ at low H₂ flow rates. Higher flow rates of hydrogen had a smaller effect.

Tandem differential mobility analysis measurements demonstrated good reproducibility for the coating study. Based on the results using sodium chloride as the core particles, all of the coating reactants, with the exception of C₂H₄, produced measurable particle growth due to photoinduced chemical vapor deposition. However, for CH₄, C₂H₆ and styrene these increases were small, corresponding to coating thicknesses of about 1 nm, and were unaffected by the reactant flow rate. C₂H₂ produced an increase-peak-decrease trend for coating thicknesses with various flow rates, with considerable carbon particles produced from gas phase nucleation even at low flow rates. Methyl methacrylate produced a monotonic increasing trend for coating thickness versus reactant flow rate and appeared to be a promising coating reactant.

A parametric study was performed to coat sodium chloride nanoparticles using methyl methacrylate as the coating precursor. Experiments were conducted within the range of methyl methacrylate flow rates where no noticeable carbon particles from photoinduced nucleation were detected. Coating thickness increased monotonically, from sub-nm to 20 nm, with increasing methyl methacrylate flow rates for different initial mobility diameters, ranging from 20 to 60 nm. The coating growth rate declined as particle size increased, but more slowly than 1/Dₚ, consistent with theory for particle growth by condensation in the transition regime.

The bandpass filter with nominally 50% transmittance was used. The concentration of the carbon particles, produced by photoinduced nucleation, was comparable to that of the background for methyl methacrylate flow rates up to 22.9 sccm. No detectable carbon particles were obtained for even higher methyl methacrylate flow rates with the use of the 10% transmittance filter. Changing the ultraviolet intensity by using the interference filters had a significant effect on coating thickness, with thicker coating for higher ultraviolet intensity at a fixed methyl methacrylate flow rate.

Compared to methyl methacrylate flow rate, the concentration of core sodium chloride particles had weaker effect on coating thickness. Lower concentration of core particles produced a small increase in coating thickness at the methyl methacrylate flow rate.

Morphology analysis with transmission electron microscopy shows that a structure of an amorphous coating shell with a sodium chloride core particle was achieved. Surface composition characterization with FTIR indicates that the coating materials had the bonding configurations characteristic of methyl methacrylate.

Tandem differential mobility analysis measurements for the coating process using aluminum nanoparticles were conducted. The effect of ultraviolet radiation on particle charge and the coating thickness measurements using different precursors such as CH₄, C₂H₂ and methyl methacrylate were similar to those of sodium chloride nanoparticles. Transmission electron microscopy characterization of the coated aluminum particles using methyl methacrylate as the precursor showed the existence of a coating layer surrounding the core particle. Different from sodium chloride particles, which are inert to the coating materials used, an interface layer can be formed between the aluminum core and the carbon coating surface. This layer was produced due to the diffusion and reaction between the coating materials and aluminum. As a result, shrinkage of the particle core was expected during the coating of aluminum nanoparticles.

### Example 2

### Coating Study Using Silver Nanoparticles

Further study of the photo-CVD nanoparticle coating process was conducted using silver nanoparticles which have been shown to image well and are not disintegrated by VUV radiation. Silver nanoparticles were synthesized by homogeneously nucleating vaporized silver in a manner developed by Scheibel et al. Journal of Aerosol Science, 14(2), 113-126 (1983). As concluded by Scheibel et al., the particle size distribution was seen to be primarily a function of tube furnace temperature. For a fixed furnace temperature of 1250° C. and nitrogen flowrate of 2 slm an initial study sought to determine whether condensation of silver vapor could produce particle concentrations that were sufficiently high enough for particle coating experiments. As shown in FIG. 18, the resulting aerosol was characterized with an SMPS system and found to have a peak particle size of 33 nm with particle counts in excess of 10⁵ part/cm³ for the polydisperse distribution. When the particles were size selected at 33 nm with a DMA before entering the chamber the particle count was decreased by a factor of 2. The concentration of particles delivered to the CPC was further decrease by an order of magnitude when the aerosol was exposed to radiation from the VUV lamp and passed through another bi-polar charger. While the particle concentration, as measured by the CPC, decreased when the aerosol was exposed to a second bi-polar charger and radiation, there was no actual decrease in particle concentration in the chamber. The drop in concentration was due to a decrease in negatively charged particles by a redistribution of particle charge states by the second bi-polar charger and particle-photon interactions. While the concentration of particles were drastically reduced by size selection and charge redistribution the resulting sampled aerosol concentration was high enough to give a representative sample of the coating process.

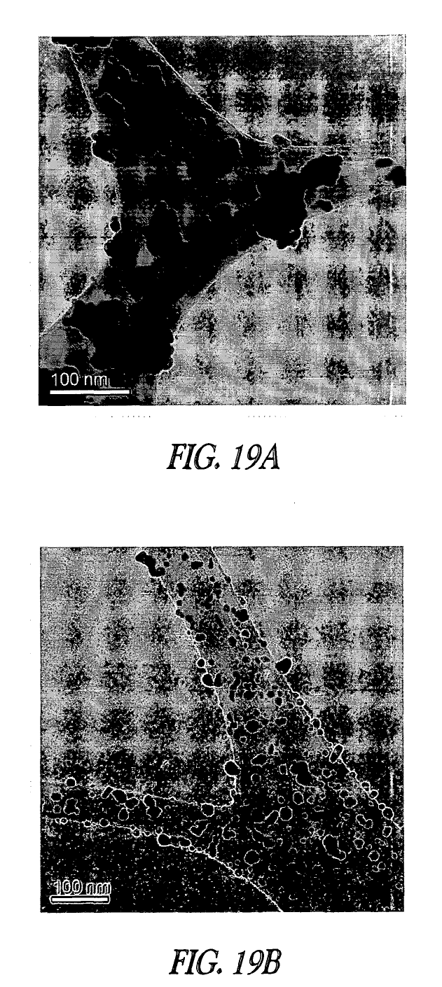

While particle counts were sufficient, TEM analysis of the particle samples produced by the Scheibel et al. method indicated that most particles were agglomerates of smaller primary particles. For fundamental study of the coating process individual spherical particles were desired for simplicity of geometry and smaller surface area per particle. Therefore a method was devised to sinter the agglomerated particles downstream of the particle nucleation point. Work by Ku and Maynard found that temperatures above 500° C. allowed silver particles sinter (Ku et al., Journal of Aerosol Science, 37(4), 452-470 (2006). To accomplish particle coalescence a second tube furnace was added to the system along with a dilution nitrogen flow to suppress further agglomeration. Particles were produced with the first tube furnace at 1250° C. and particles were collected with and without the second tube furnace at 600° C. The results of sintering can be seen in FIG. 19 where the large agglomerates found in FIG. 19A, were reduced by dilution and sintering forming individual particles, FIG. 19B. While the particles are largely sintered they nave not completely coalesced into spheres. Higher temperatures of the second tube furnace (>700° C.) will likely provide enough energy to fully coalesce the particles.

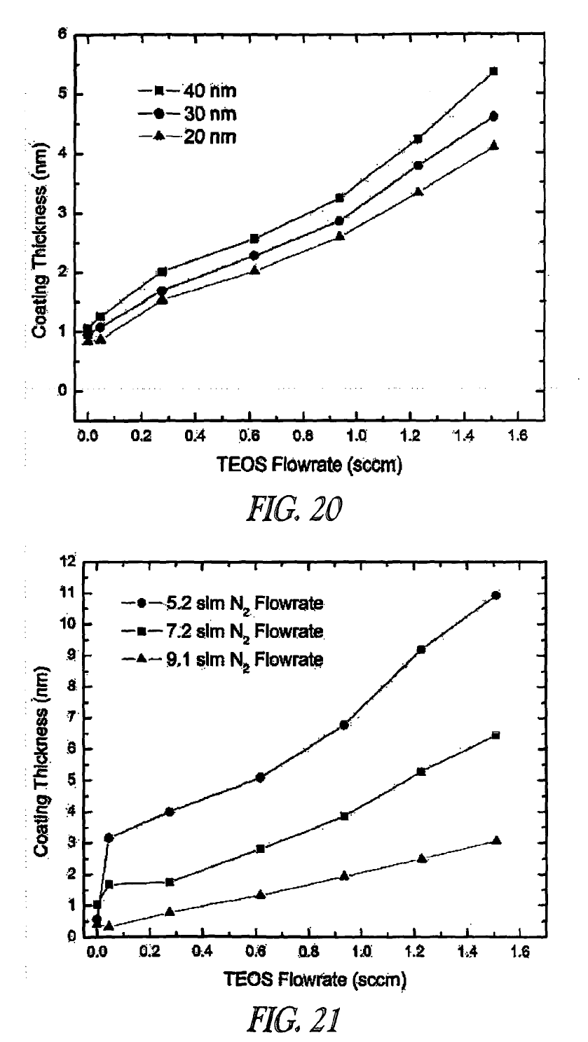

The sintered silver nanoparticles served as effective substrates for coating studies of critical system parameters. In order to determine the effect that particle size has on coating thickness the silver particles were size selected with three different particle mobilities that corresponded to 20, 30, and 40 nm aerodynamic diameters. The particles were then coated using the photo-CVD process with operating conditions of 7.2 slm purge nitrogen flow, 3 slm tube furnace nitrogen flow, and tube furnace temperatures as stated above. The particle coating thickness was measured using the TDMA system and plotted as a function of TEOS flowrate and particle size. As shown in FIG. 20 the coating thickness increased nearly linear over the range of TEOS flowrates measured. The difference in coating thickness was contrary to what theory predicts for particles in the transition regime which is a 1/dₚ for coating thickness. Further study is needed with fully coalesced spherical particles so that the theory can be accurately applied to a system with all spherical particles.

To determine the effect of variations in the nitrogen purge flowrate, the coating thickness was measured for a range of TEOS flows with three different nitrogen purge flowrates. Size selected 30 nm particles were coated with three different nitrogen purge flowrates and range of TEOS flowrates with all other conditions similar to the previous experiment. The resulting coating thicknesses were measured using TDMA analysis and shown in FIG. 21. As in the previous FIG. 20, the coatings appeared to grow linearly with TEOS flowrate over the range of flows tested. The nitrogen purge flowrate also influenced the coating thickness by more than doubling the thickness of the coating over the range of purge flowrates for any given TEOS flow. The low flowrates of nitrogen purge gas increased coating thickness by increasing particle and precursor concentration as well as increasing resonance time. While the decrease purge flowrate increased coating thickness, it also increased coating variability as measured by the increase in the standard deviation of the Gaussian fits to the size distributions which varied from 3.4 to 8.4 for purge flowrates of 5.2 and 9.1 respectively.

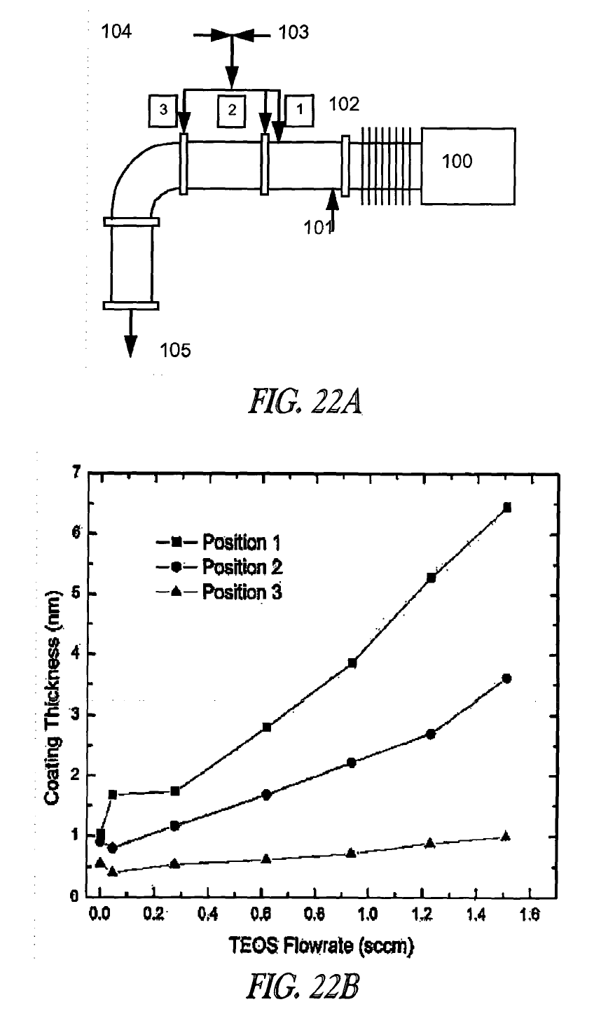

A study of differing aerosol and TEOS inlet positions sought to determine how spatial variations of the system could affect the resulting coating thickness. As inlet positions were moved from a location close to the lamp to farther down the chamber both the residence time and radiation reaching the particles and intensity were decreased. At each inlet position size selected 30 nm particles were passed into the chamber with a nitrogen purge flow of 7.2 slm and varying flowrates of TEOS. A schematic of inlet positions and resulting coating thicknesses for variations in inlet positing and TEOS flowrates is shown in FIG. 22, wherein reference numeral 100 is the lamp, reference numeral 101 is the N₂ purge, reference numeral 103 is the inlet position, reference numeral 104 is the monodisperse aerosol, reference numeral 105 is the precursor inlet, reference numeral 106 is the outlet to DMA and CPC. As shown, the coating thicknesses decreased dramatically as the inlet positions were moved down the tube and away from the excimer lamp. These results along with those from FIG. 21 highlight the impact of resonance time in the system.

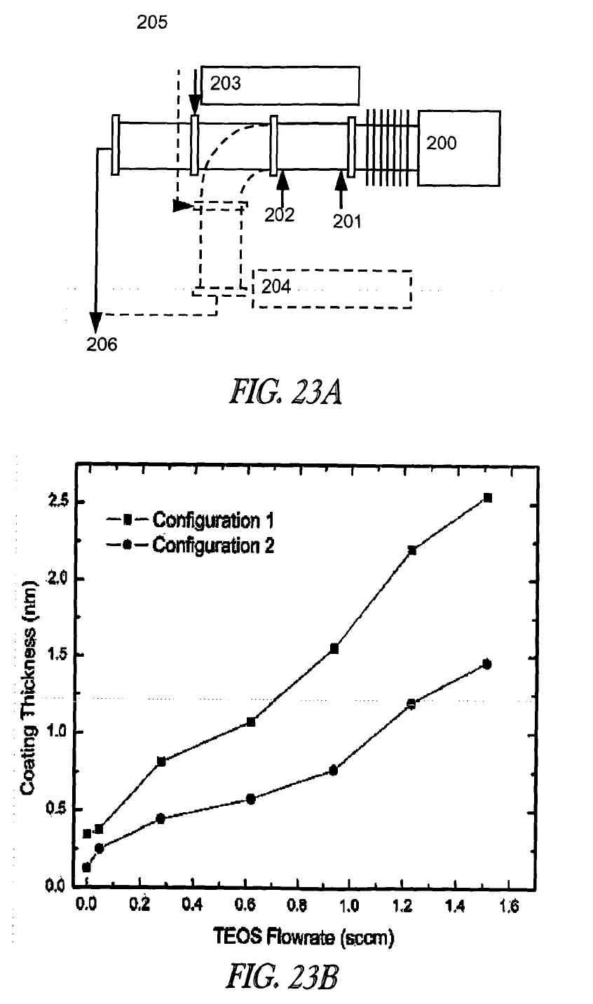

To determine whether UV light must be present at the surface of the particle in order to create a coating on the particle coating, the system was modified so that the TEOS and aerosol were input into the chamber at different positions. The TEOS was input up stream of the aerosol and in view of the lamp. The aerosol inlet was placed 12.7 cm downstream of the TEOS inlet in two different configurations. The first configuration placed the particles in direct view of the lamp and thus exposed to the radiation intensity while the second inlet was around a 90° bend and out of the presence of radiation as shown in FIG. 23A, wherein reference numeral 200 is the lamp, reference numeral 201 is the N₂ purge, reference numeral 202 is the TEOS inlet, reference numeral 203 is the configuration 1, reference numeral 204 is the configuration 2, reference numeral 205 is polydisperse aerosol, and reference numeral 206 is the outlet to DMA and CPC. For both configurations size selected 30 nm particles were inserted into the chamber with 7.2 slm of nitrogen purge flow and the coating thicknesses were measured. As shown in FIG. 23B, the coating thickness for the particles that were exposed to radiation had a thicker coating than those that were not. However, the presence of a coating on the particles in Configuration 2 indicates that particle coatings do not require the presence of radiation on the surface to create coatings. It remains unclear whether the increased thickness of the coatings in Configuration 1 was due the presence of the VUV radiation or a result of less precursor loss to the tube wall from not having a bend in the pipe.

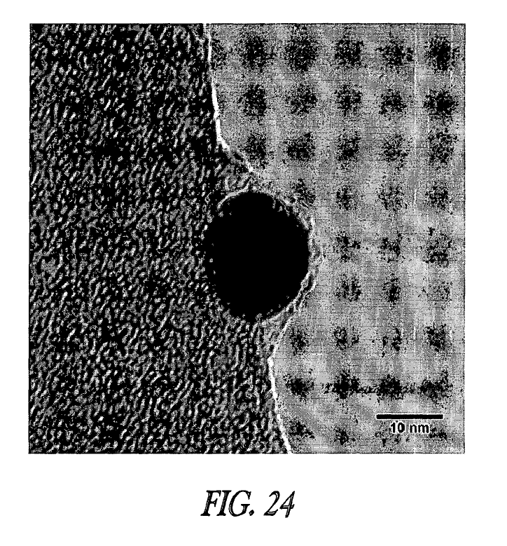

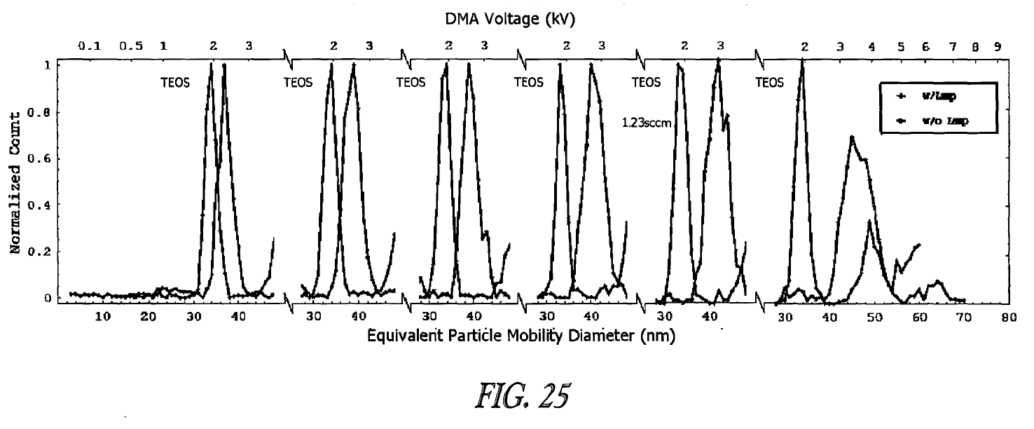

To confirm the particle coatings high resolution TEM analysis was conducted on samples collected from size selected 20 nm particles coated with a TEOS flowrate of 1.2 sccm and nitrogen purge flowrate of 7.2 slm. The average coating thickness, as determined by TDMA measurements, was found to be slightly less than 3 nm over the 75 min collection time. The resulting coated particles, as seen in FIG. 24, exhibited core-shell structures that agreed well with the TDMA measurements. The particle shown in FIG. 24 was representative of all particles found on the sample indicating a low degree of variability for the coating process. While TEM imaging can confirm the presence of material with different atomic density, EDX must be performed to fully characterize the particle coating.

### Example 3

### Coating Study Using Yttrium Aluminum Oxide Nanoparticles

For the study of coatings on yttrium aluminum oxide particles, YAP particles were selected for initial testing because they were commercially available at submicron sizes. Colloidal solutions were prepared using nGmat YAP powder dispersed in methanol at 0.01 Molarity and aerosolized in a manner similar to the sodium chloride and PSL nebulization. The methanol was removed from the aerosol by passing the aerosol through a diffusion dryer that contained molecular sieves. The sieves were selected with an effective pore size of 3 Å which was large enough to remove methanol molecules from the flowstream. The YAP aerosol was size selected at 35 nm and then mixed with TEOS at various flowrates and passed into chamber where VUV radiation initiated coating growth. The resulting size shifts were determined by TDMA measurements of particle diameter, as shown in FIG. 25. As seen the YAP particle diameter grows with TEOS flowrate similar to sodium chloride particle growth. While the particle growth is similar for both sodium chloride and YAP particles the particle distributions of coated YAP are significantly narrower at high TEOS flowrates and do not become unstable at 1.51 sccm.

The particle coating thickness versus TEOS flowrate was determined in the same manner as silver particles. The coating thickness was measured for two different VUV radiation intensities which were controlled by varying the lamp window transmissivity via the selection of window material. A thermopile radiation detector measured radiation intensities transmitted by a calcium florid and silica window. The transmitted intensity was found to be 7.5 mW/cm² and 15 mW/cm² for the silica and calcium fluoride windows respectively. Measurements from the thermopile detector were not accurate enough to give absolute values of the intensity but were good indications of relative intensity. Therefore, it can be concluded that the transmitted radiation intensity of the silica window was half that of the calcium fluoride window.

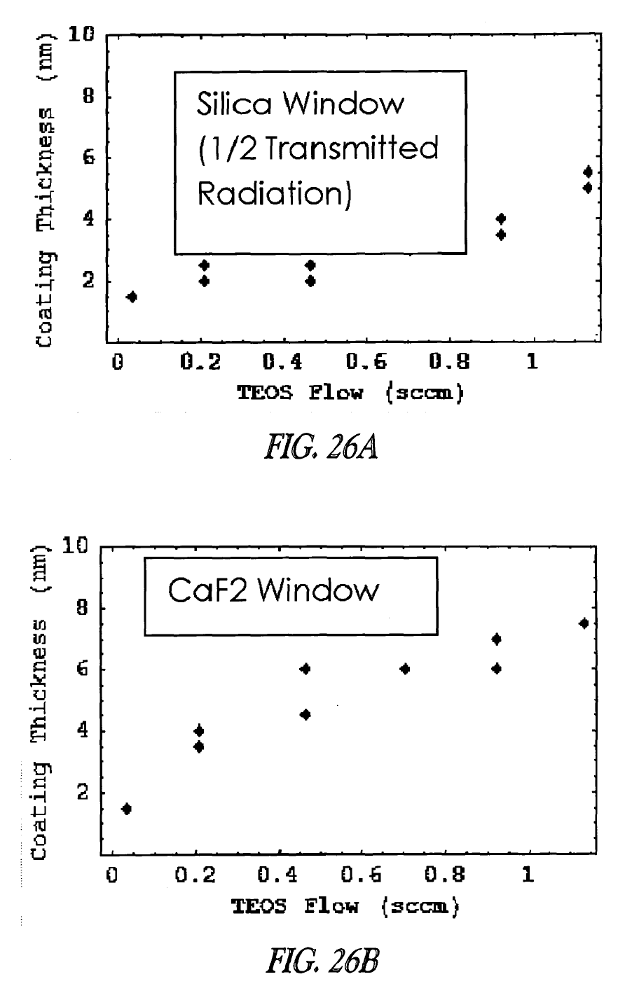

The coated YAP particle sizes were measured for systems with both the calcium fluoride and silica windows with a 7.2 slm nitrogen purge flowrate and a variety of TEOS flowrates. The resulting coating thickness for the two different radiation intensities are shown in FIG. 26. As seen the coating thickness produced using the calcium fluoride window was significantly thicker at higher TEOS flowrates than coatings that were produced using the silica window. At lower TEOS flowrates, however, both coatings were nearly the same. This result indicates that the VUV intensity in the chamber was high enough with either window to dissociate all of the TEOS at lower flowrates, resulting in the same coating thickness. For higher TEOS flowrates the lower transmitted intensity of the silica window does not disassociate as much TEOS as the calcium fluoride window, resulting in thinner coatings.

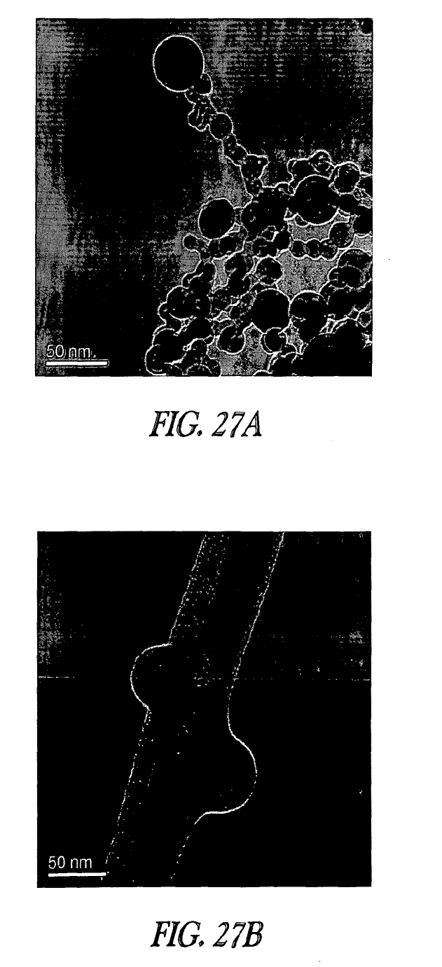

Images of coated YAP particles were obtained by TEM analysis of particles collected with and without coatings, as shown in FIG. 27. The sample depicted in FIG. 27B consisted of size selected 40 nm particles that were coated with reactor conditions of 4.3 slm nitrogen flow and 0.9 sccm TEOS. The particles were gathered for 60 minutes onto a lacey carbon TEM grid via an electrostatic precipitator. The sample depicted in FIG. 27A was made by placing a droplet of the YAP solution on a TEM grid and allowing the solvent to evaporate off. As seen in FIG. 27B the particle coating appears to be in good agreement with the coating thickness reported for particles of similar size and flowrate in FIG. 26. The particle coatings appear uniform around the particle, but necks into the lacy carbon grid at the point of contact to the grid.

All patents and publications referenced or mentioned herein are indicative of the levels of skill of those skilled in the art to which the invention pertains, and each such referenced patent or publication is hereby incorporated by reference to the same extent as if it had been incorporated by reference in its entirety individually or set forth herein in its entirety. Applicant reserves the right to physically incorporate into this specification any and all materials and information from any such cited patents or publications.

The specific methods and compositions described herein are representative of preferred embodiments and are exemplary and not intended as limitations on the scope of the invention. Other objects, aspects, and embodiments will occur to those skilled in the art upon consideration of this specification, and are encompassed within the spirit of the invention as defined by the scope of the claims. It will be readily apparent to one skilled in the art that varying substitutions and modifications may be made to the invention disclosed herein without departing from the scope and spirit of the invention. The invention illustratively described herein suitably may be practiced in the absence of any element or elements, or limitation or limitations, which is not specifically disclosed herein as essential. The methods and processes illustratively described herein suitably may be practiced in differing orders of steps, and that they are not necessarily restricted to the orders of steps indicated herein or in the claims.

1. A method comprising:
exposing aerosolized nanoparticles to a gas-phase reactant and to ultraviolet radiation simultaneously; and
depositing a coating on one or more surfaces of the aerosolized nanoparticles to form coated nanoparticles, the coating having a thickness.

2. The method of claim 1, further comprising controlling the thickness by varying a flow rate of the aerosolized nanoparticles, varying a flow rate of the gas-phase reactant, varying a flow rate of an optional purge gas, or a combination thereof.

3. The method of claim 1, wherein the ultraviolet radiation is transmitted through an ultraviolet interference filter before the exposing step.

4. The method of claim 1, further comprising generating the ultraviolet radiation with an excimer lamp.

5. The method of claim 1, wherein the exposing step is carried out at a temperature from about −100° C. to about 600° C.

6. The method of claim 1, wherein the exposing step is carried out at a pressure from about 0.5 kPa to about 500 kPa.

7. The method of claim 1, wherein the ultraviolet radiation has a wavelength from about 80 nm to about 400 nm.

8. The method of claim 2, wherein the flow rate of aerosolized nanoparticles is from about 0.1 sccm to about 5000 sccm, the flow rate of the gas-phase reactant is from about 0.1 sccm to about 10,000 sccm, and the optional flow rate of an optional purge gas is from about 0.1 sccm to about 50,000 sccm.

9. The method of claim 1, wherein the aerosolized nanoparticles comprise nonpolymeric inorganic materials, polymeric inorganic materials, nonpolymeric organic materials, polymeric organic materials, or a combination thereof.

10. The method of claim 1, wherein the coating comprises an organic coating, an inorganic coating, or a hybrid organic-inorganic coating.

11. A method of coating nanoparticles comprising:
introducing a flow of aerosolized nanoparticles into a coating reactor;
introducing a flow of a gas-phase reactant into the coating reactor;
exposing the coating reactor to ultraviolet radiation, wherein the ultraviolet radiation is generated with an excimer lamp;
depositing a coating on one or more surfaces of the aerosolized nanoparticles, the coating having a thickness; and
controlling the thickness of the coating.

12. The method of claim 11, wherein the controlling step comprises varying a flow rate of the aerosolized nanoparticles, varying a flow rate of the gas-phase reactant, or a combination thereof.

13. The method of claim 11, wherein the ultraviolet radiation is transmitted through an ultraviolet interference filter before exposing the coating reactor.

14. The method of claim 11, further comprising generating the ultraviolet radiation with an excimer lamp.

15. The method of claim 11, wherein the exposing step is carried out at a temperature from about −100° C. to about 600° C.

16. The method of claim 11, wherein the exposing step is carried out at a pressure from about 0.5 kPa to about 500 kPa.

17. The method of claim 11, wherein the ultraviolet radiation has a wavelength of about 80 nm to about 400 nm.

18. A nanoparticle coating system comprising:
a coating reactor;
a gas-phase reactant source coupled to the coating reactor;
an aerosolized nanoparticles source coupled to the coating reactor; and
an ultraviolet radiation source configured to expose the coating reactor to ultraviolet radiation.

19. The system of claim 18, further comprising an ultraviolet interference filter for transmitting the ultraviolet radiation.

20. The system of claim 18, wherein the ultraviolet radiation source comprises an excimer lamp.

21. The method of claim 11 further comprising introducing a purge gas into the coating reactor.

22. The system of claim 18 further comprising a purge gas source coupled to the coating reactor.
